(19) United States
(12) Patent Application Publication
(10) Pub. No.: US 2021/0367390 A1
(43) Pub. Date: Nov. 25, 2021

(54) GAS LASER APPARATUS, AND ELECTRONIC DEVICE MANUFACTURING METHOD

(71) Applicant: Gigaphoton Inc., Tochigi (JP)

(72) Inventors: Daisuke TEI, Oyama-shi (JP); Osamu WAKABAYASHI, Oyama-shi (JP); Makoto TANAKA, Oyama-shi (JP); Miwa IGARASHI, Oyama-shi (JP)

(73) Assignee: Gigaphoton Inc., Tochigi (JP)

(21) Appl. No.: 17/398,161

(22) Filed: Aug. 10, 2021

Related U.S. Application Data
(63) Continuation of application No. PCT/JP2019/013160, filed on Mar. 27, 2019.

(51) Int. Cl. H01S 3/036; G03F 7/20; H01S 3/041

(52) U.S. Cl. CPC H01S 3/036; H01S 3/041; G03F 7/2053; G03F 7/70025

(57) ABSTRACT

A gas laser apparatus may include a chamber filled with a laser gas; a window provided in the chamber and through which a laser beam passes; an optical path tube connected to the chamber to surround a position of the window in the chamber; a heated gas supply port configured to supply a heated purge gas into a closed space including a space in the optical path tube; and an exhaust port configured to exhaust a gas in the closed space.

### CROSS-REFERENCE TO RELATED APPLICATIONS

The present application is a continuation application of International Application No. PCT/JP2019/013160, filed on Mar. 27, 2019, the entire contents of which are hereby incorporated by reference.

### BACKGROUND

### 1. Technical Field

The present disclosure relates to a gas laser apparatus, and an electronic device manufacturing method.

### 2. Related Art

Recently, improvement in resolution of semiconductor exposure apparatuses (hereinafter referred to as “exposure apparatuses”) has been desired due to miniaturization and high integration of semiconductor integrated circuits. For this purpose, exposure light sources that output light with shorter wavelengths have been developed. As the exposure light source, a gas laser apparatus is generally used in place of a conventional mercury lamp. For example, as a gas laser apparatus for exposure, a KrF excimer laser apparatus that outputs an ultraviolet laser beam having a wavelength of 248 nm and an ArF excimer laser apparatus that outputs an ultraviolet laser beam having a wavelength of 193 nm are used.

As next generation exposure technology, immersion exposure is practically used in which a gap between an exposure lens of an exposure apparatus and a wafer is filled with a liquid. In the immersion exposure, a refractive index between the exposure lens and the wafer changes to shorten an apparent wavelength of light from an exposure light source. When the immersion exposure is performed using the ArF excimer laser apparatus as the exposure light source, the wafer is irradiated with ultraviolet light having a wavelength of 134 nm in water. This technology is referred to as ArF immersion exposure (or ArF immersion lithography).

The KrF excimer laser apparatus and the ArF excimer laser apparatus have a large natural oscillation range of about 350 to 400 pm. Thus, if a projection lens is made of a material that transmits ultraviolet light such as KrF and ArF laser beams, chromatic aberration may occur, thereby reducing resolution. Then, a spectral line width of a laser beam output from the gas laser apparatus needs to be narrowed to the extent that the chromatic aberration can be ignored. For this purpose, a line narrowing module (LNM) having a line narrowing element such as etalon or grating is sometimes provided in a laser resonator of the gas laser apparatus to narrow the spectrum line width. A laser apparatus in which the spectrum line width is narrowed is hereinafter referred to as a line narrowing laser apparatus.

### LIST OF DOCUMENTS

### Patent Documents

Patent Document 1: Japanese Unexamined Utility Model Application Publication No. 01-129964
Patent Document 2: Japanese Unexamined Patent Application Publication No. 55-108788

### SUMMARY

One aspect of the present disclosure may be a gas laser apparatus including a chamber filled with a laser gas; a window provided in the chamber and through which a laser beam passes; an optical path tube connected to the chamber to surround a position of the window in the chamber; a heated gas supply port configured to supply a heated purge gas into a closed space including a space in the optical path tube; and an exhaust port configured to exhaust a gas in the closed space.

Another aspect of the present disclosure may be an electronic device manufacturing method including causing a laser beam emitted from a gas laser apparatus to enter an exposure apparatus; and exposing a photosensitive substrate to the laser beam within the exposure apparatus to manufacture an electronic device, the gas laser apparatus including a chamber filled with a laser gas, a window provided in the chamber and through which the laser beam passes, an optical path tube connected to the chamber to surround a position of the window in the chamber, a heated gas supply port configured to supply a heated purge gas into a closed space including a space in the optical path tube, and an exhaust port configured to exhaust a gas in the closed space.

### BRIEF DESCRIPTION OF THE DRAWINGS

With reference to the accompanying drawings, some embodiments of the present disclosure will be described below merely by way of example.

FIG. 1 is a schematic diagram of an exemplary configuration of the entire manufacturing device used in an exposure process in manufacture of an electronic device.

FIG. 2 is a schematic diagram of an exemplary configuration of the entire gas laser apparatus of a comparative example.

FIG. 3 is a schematic diagram of a configuration of the entire gas laser apparatus of Embodiment 1.

FIG. 4 shows a configuration of a section from one window provided in a chamber to a laser beam exit window provided in a casing.

FIG. 5 shows a configuration of a section from the other window provided in the chamber to a line narrowing module.

FIG. 6 shows a configuration of a section from one window provided in a chamber to a laser beam exit window provided in a casing in a gas laser apparatus of Embodiment 2.

FIG. 7 is a front view of a window cover.

FIG. 8 shows a variant of the window cover.

FIG. 9 shows a configuration of a section from one window provided in a chamber to a laser beam exit window provided in a casing in a gas laser apparatus of Embodiment 3.

FIG. 10 shows a configuration of a section from one window provided in a chamber to a laser beam exit window provided in a casing in a gas laser apparatus of Embodiment 4.

FIG. 11 shows a variant of the gas laser apparatus of Embodiment 4.

FIG. 12 shows another variant of the gas laser apparatus of Embodiment 4.

FIG. 13 is a schematic diagram of a configuration of essential portions of a gas laser apparatus of Embodiment 5.

FIG. 14 is a schematic diagram of an exemplary configuration of the entire gas laser apparatus of Embodiment 6.

FIG. 15 shows a configuration of a section from one window provided in a chamber of an amplifier to an optical transmission unit in FIG. 14.

FIG. 16 shows a configuration of a section from the other window provided in the chamber of the amplifier to an optical transmission unit in FIG. 14.

### DESCRIPTION OF EMBODIMENTS

1. Description of manufacturing device used in exposure process in manufacture of electronic device
2. Description of gas laser apparatus of comparative example

2.1 Configuration

2.2 Operation

2.3 Problem
3. Description of gas laser apparatus of Embodiment 1

3.1 Configuration

3.2 Operation

3.3 Effect
4. Description of gas laser apparatus of Embodiment 2

4.1 Configuration

4.2 Effect
5. Description of gas laser apparatus of Embodiment 3

5.1 Configuration

5.2 Effect
6. Description of gas laser apparatus of Embodiment 4

6.1 Configuration

6.2 Effect
7. Description of gas laser apparatus of Embodiment 5

7.1 Configuration

7.2 Effect
8. Description of gas laser apparatus of Embodiment 6

8.1 Configuration

8.2 Operation

8.3 Effect

Now, with reference to the drawings, embodiments of the present disclosure will be described in detail.

The embodiments described below illustrate some examples of the present disclosure, and do not limit contents of the present disclosure. Also, all configurations and operations described in the embodiments are not necessarily essential as configurations and operations of the present disclosure. The same components are denoted by the same reference numerals, and overlapping descriptions are omitted.

### 1. Description of Manufacturing Device Used in Exposure Process in Manufacture of Electronic Device

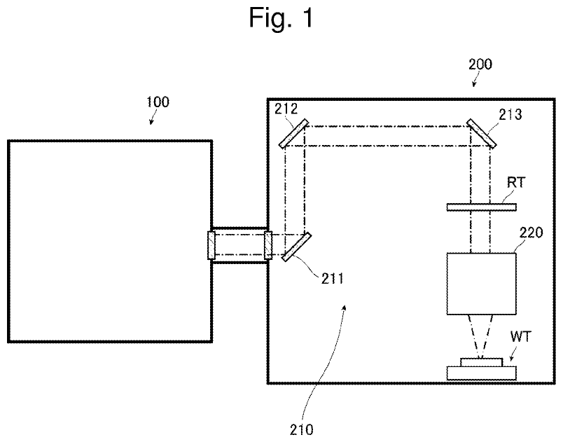

FIG. 1 is a schematic diagram of an exemplary configuration of the entire manufacturing device used in an exposure process in manufacture of an electronic device. As shown in FIG. 1, the manufacturing device used in the exposure process includes a gas laser apparatus 100 and an exposure apparatus 200. The exposure apparatus 200 includes an illumination optical system 210 including a plurality of mirrors 211, 212, 213, and a projection optical system 220. The illumination optical system 210 illuminates, with a laser beam incident from the gas laser apparatus 100, a reticle pattern on a reticle stage RT. The projection optical system 220 reduces and projects the laser beam having passed though the reticle and forms an image thereof on a workpiece (not shown) arranged on a workpiece table WT. The workpiece is a photosensitive substrate such as a semiconductor wafer coated with photoresist. The exposure apparatus 200 synchronously translates the reticle stage RT and the workpiece table WT to expose the workpiece to the laser beam reflecting the reticle pattern. Through the exposure process as described above, a device pattern is transferred onto the semiconductor wafer, thereby manufacturing a semiconductor device as an electronic device.

### 2. Description of Gas Laser Apparatus of Comparative Example

2.1 Configuration

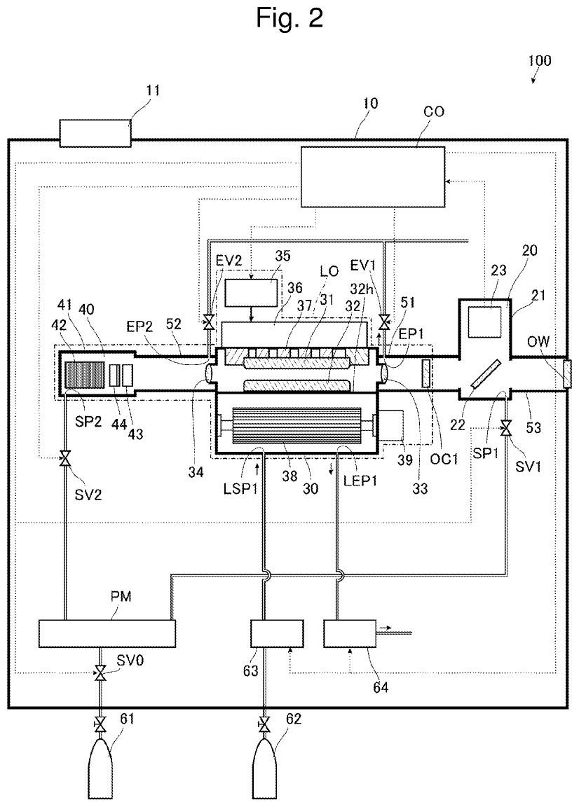

A gas laser apparatus of a comparative example will be described. FIG. 2 is a schematic diagram of an exemplary configuration of the entire gas laser apparatus of this example. As shown in FIG. 2, a gas laser apparatus 100 of this example mainly includes a casing 10, a laser oscillator LO, an energy monitor module 20, and a control unit CO. The gas laser apparatus 100 of this example is an ArF excimer laser apparatus using a mixed gas containing, for example, argon (Ar), fluorine (F 2), and neon (Ne). In this case, the gas laser apparatus 100 emits a pulse laser beam having a central wavelength of about 193 nm. The gas laser apparatus 100 may be a gas laser apparatus other than the ArF excimer laser apparatus, and for example, may be a KrF excimer laser apparatus using a mixed gas containing krypton (Kr), fluorine (F₂), and neon (Ne). In this case, the gas laser apparatus 100 emits a pulse laser beam having a central wavelength of about 248 nm. The mixed gas containing Ar, F₂, and Ne or the mixed gas containing Kr, F₂, and Ne as a laser medium is sometimes referred to as a laser gas.

The control unit CO can use, for example, an integrated circuit such as a microcontroller, an integrated circuit (IC), a large-scale integrated circuit (LSI), or an application specific integrated circuit (ASIC), or a numerical control (NC) device. When using the NC device, the control unit CO may or may not use a machine leaning device. As described below, the control unit CO controls some components of the gas laser apparatus 100.

The laser oscillator LO mainly includes a chamber 30, a pair of electrodes 31, 32, a pair of windows 33, 34, a charger 35, a pulse power module 36, a cross flow fan 38, a motor 39, a line narrowing module 40, and an output coupling mirror OC1.

The chamber 30 is a casing made of metal and filled with a laser gas. The electrodes 31, 32 excite the laser medium by discharge, and are arranged to face each other in the chamber 30.

The chamber 30 has an opening, which is closed by an insulating portion 37 including an insulator. The electrode 31 is supported by the insulating portion 37. A feedthrough formed of a conductive member is embedded in the insulating portion 37. The feedthrough applies a voltage supplied from the pulse power module 36 to the electrode 31. The electrode 32 is supported by an electrode holder 32h. The electrode holder 32h is secured to an inner surface of the chamber 30, and electrically connected to the chamber 30.

The charger 35 is a DC power supply device that charges a capacitor (not shown) provided in the pulse power module 36 with a predetermined voltage. The pulse power module 36 includes a switch controlled by the control unit CO. When the switch is turned on, the pulse power module 36 increases the voltage applied from the charger 35 to generate a pulsed high voltage, and applies the high voltage between the electrodes 31, 32.

The cross flow fan 38 is arranged in the chamber 30. A space in which the cross flow fan 38 is arranged communicates with a space between the electrodes 31, 32 in the chamber 30. Thus, the cross flow fan 38 rotates to circulate the laser gas filling the chamber 30 in a predetermined direction. The motor 39 arranged outside the chamber 30 is connected to the cross flow fan 38. The motor 39 rotates to rotate the cross flow fan 38. The motor 39 is turned on/off or adjusted in rotation speed by control with the control unit CO. Thus, the control unit CO can control the motor 39 to adjust a circulation speed of the laser gas circulating in the chamber 30.

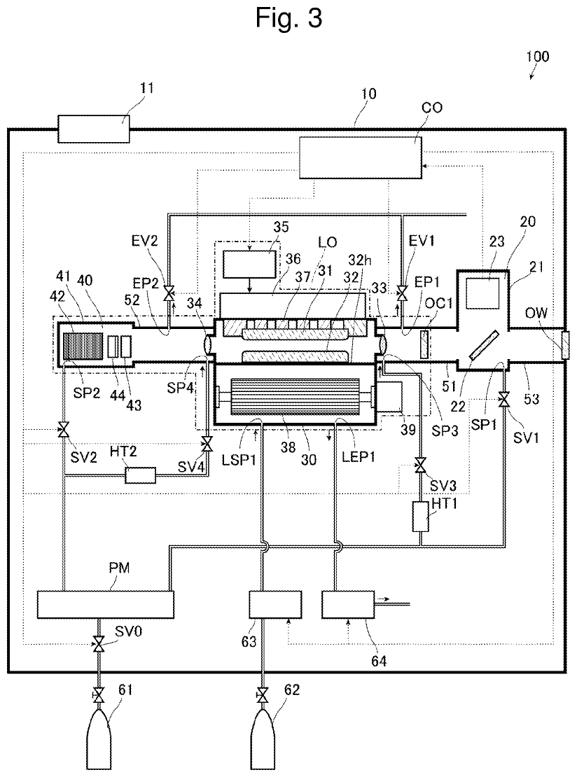

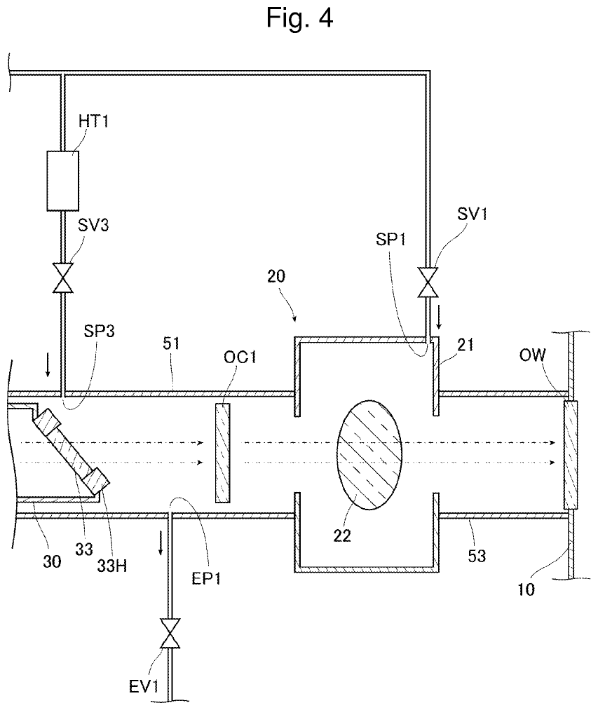

The windows 33, 34 are provided to face each other with a space therebetween, the space being between the electrode 31 and the electrode 32 in the chamber 30. One window 33 is provided at one end of the chamber 30 in a traveling direction of the laser beam, and the other window 34 is provided at the other end of the chamber 30 in the traveling direction of the laser beam. The windows 33, 34 are secured to the chamber 30 by window holders 33H, 34H shown in FIGS. 3 and 4. As described later, in the gas laser apparatus 100, light oscillates in an optical path including the chamber 30 to emit the laser beam, and thus the laser beam generated in the chamber 30 is emitted through the windows 33, 34 to the outside of the chamber 30. The windows 33, 34 are arranged to suppress reflection of a P-polarized component of the laser beam from a surface through which the laser beam passes. Specifically, when the windows 33, 34 are formed of parallel planar substrates, the windows 33, 34 may be arranged such that an incident angle of the laser beam on any plane is a Brewster's angle. As such, the windows 33, 34 are tilted with respect to the traveling direction of the laser beam. The windows 33, 34 are made of, for example, calcium fluoride. The windows 33, 34 may be coated with a fluoride or oxide film.

An optical path tube 51 is connected to the one end of the chamber 30 at which the window 33 is provided. The optical path tube 51 is a cylindrical member made of metal. A position of the window 33 in the chamber 30 protrudes into the optical path tube 51 with a gap from an inner wall of the optical path tube 51. Thus, the window 33 is located in the optical path tube 51.

An optical path tube 52 is connected to the other end of the chamber 30 at which the window 34 is provided. The optical path tube 52 is a cylindrical member made of metal. A position of the window 34 in the chamber 30 protrudes into the optical path tube 52 with a gap from an inner wall of the optical path tube 52. Thus, the window 34 is located in the optical path tube 52.

The output coupling mirror OC1 is provided on the one end side of the chamber 30, and arranged in the optical path tube 51. The output coupling mirror OC1 is an optical element that the laser beam emitted through the window 33 enters. The output coupling mirror OC1 transmits one part of the laser beam emitted through the window 33, and reflects and returns the other part through the window 33 into the chamber 30. The output coupling mirror OC1 is formed of, for example, an element including a calcium fluoride substrate coated with a dielectric multilayer film.

The line narrowing module 40 is connected to the optical path tube 52. Thus, the line narrowing module 40 is provided on the other end side of the chamber 30. The line narrowing module 40 includes a casing 41, a grating 42, and prisms 43, 44. The casing 41 is made of, for example, metal and has an opening, through which a space in the casing 41 communicates with a space in the optical path tube 52. The casing 41, the optical path tube 52, part of the chamber 30, and the window 34 form a closed space, which includes the space in the optical path tube 52.

The grating 42 and the prisms 43, 44 are arranged in the casing 41. The grating 42 and the prisms 43, 44 are optical elements that the laser beam emitted through the window 34 enters. The grating 42 is configured in a Littrow arrangement such that a wavelength dispersion surface substantially matches a plane perpendicular to a propagating direction of the laser beam and that an incident angle of the laser beam substantially matches a diffraction angle thereof. In this example, the grating 42 may be an echelle grating blazed for a wavelength of about 193 nm.

At least one of the prisms 43, 44 is secured on a rotary stage, and the one of the prisms 43, 44 secured on the rotary stage slightly rotates around an axis perpendicular to a wavelength dispersion direction of the grating 42 to adjust an incident angle of light on the grating 42. The incident angle of the light on the grating 42 is adjusted to adjust a reflection angle of the light reflected by the grating 42. Thus, the light emitted through the window 34 is reflected by the grating 42 through the prisms 43, 44 and again enters the window 34 through the prisms 43, 44 to adjust the wavelength of the light returning to the chamber 30 to a desired wavelength. In this example, the two prisms are arranged in the line narrowing module 40, but one or three or more prisms may be arranged.

The output coupling mirror OC1 and the grating 42 with the chamber 30 therebetween constitute an optical resonator, and the chamber 30 is arranged in an optical path of the optical resonator. Thus, the light emitted from the chamber 30 reciprocates between the grating 42 in the line narrowing module 40 and the output coupling mirror OC1 and is amplified every time it passes through a laser gain space between the electrodes 31, 32. Part of the amplified light passes through the output coupling mirror OC1 and is emitted as a pulse laser beam.

The energy monitor module 20 is arranged in an optical path of the pulse laser beam emitted from the output coupling mirror OC1 in the laser oscillator LO. The energy monitor module 20 includes a casing 21, a beam splitter 22, and a pulse energy sensor 23. The casing 21 is connected to the optical path tube 51. The beam splitter 22 and the pulse energy sensor 23 are optical elements that the laser beam emitted through the window 33 enters. The casing 21 has an opening, through which a space in the casing 21 communicates with a space in the optical path tube 51. The beam splitter 22 and the pulse energy sensor 23 are arranged in the casing 21.

The beam splitter 22 transmits the pulse laser beam emitted from the laser oscillator LO with high transmittance, and reflects part of the pulse laser beam toward a light receiving surface of the pulse energy sensor 23. The pulse energy sensor 23 detects pulse energy of the pulse laser beam having entered the light receiving surface, and outputs data of the detected pulse energy to the control unit CO.

An opening is formed on the side of the casing 21 of the energy monitor module 20 opposite to the side to which the optical path tube 51 is connected, and an optical path tube 53 is connected to surround the opening. Thus, the space in the optical path tube 51, the space in the casing 21, and a space in the optical path tube 53 communicate with each other. The optical path tube 53 is a cylindrical member made of metal and connected to the casing 10. A laser beam exit window OW is provided in a position of the casing 10 surrounded by the optical path tube 53. Thus, the laser beam exit window OW, part of the casing 10, the optical path tube 53, the casing 21, the optical path tube 51, part of the chamber 30, and the window 33 form a closed space, which includes the space in the optical path tube 51. The laser beam passing through the beam splitter 22 in the energy monitor module 20 is emitted through the optical path tube 53 and through the laser beam exit window OW to the outside of the casing 10.

A purge gas supply source 61 storing a purge gas is arranged outside the casing 10. The purge gas contains an inert gas. The inert gas is preferably high purity nitrogen containing few impurities such as oxygen, but may contain a gas such as a rare gas. A pipe is connected to the purge gas supply source 61 and extends into the casing 10. A gas supply valve SV0 is provided in the middle of the pipe. Opening of the gas supply valve SV0 is adjusted according to a control signal from the control unit CO. The pipe having the gas supply valve SV0 is connected to a purge gas manifold PM.

A plurality of pipes are connected to the purge gas manifold PM, and a gas supply valve SV1 is provided in the middle of one of the pipes. Opening of the gas supply valve SV1 is adjusted according to a control signal form the control unit CO. The pipe having the gas supply valve SV1 is connected to the casing 21 of the energy monitor module 20. The connection is a gas supply port SP1 that supplies the purge gas into the casing 21. Thus, the gas supply port SP1 is provided on the side of the output coupling mirror OC1 opposite to the window 33, and supplies the purge gas through the casing 21 into the optical path tube 51 and the optical path tube 53.

A gas supply valve SV2 is provided in the middle of another pipe connected to the purge gas manifold PM. Opening of the gas supply valve SV2 is adjusted according to a control signal from the control unit CO. The pipe having the gas supply valve SV2 is connected to the casing 41 of the line narrowing module 40. The connection is a gas supply port SP2 that supplies the purge gas into the casing 41. In this example, the gas supply port SP2 is provided on the side of at least part of the grating 42 and the prisms 43, 44 opposite to the window 34, and supplies the purge gas through the casing 41 into the optical path tube 52.

A pipe having an exhaust valve EV1 is connected to the optical path tube 51. Opening of the exhaust valve EV1 is adjusted according to a control signal from the control unit CO. The exhaust valve EV1 opens to exhaust the gas in the optical path tube 51. The connection of the pipe having the exhaust valve EV1 to the optical path tube 51 is an exhaust port EP1 that exhausts the gas in the optical path tube 51. In this example, the exhaust port EP1 is provided beside the window 33 in the optical path tube 51. The purge gas supplied through the gas supply port SP1 is mixed with the gas in the casing 21, the optical path tube 51, and the optical path tube 53, and flows to the exhaust port EP1. Thus, the purge gas can reduce an oxygen concentration in the casing 21, the optical path tube 51, and the optical path tube 53, and the reduced oxygen concentration can be maintained. This can suppress absorption of the pulse laser beam by oxygen, and allow efficient output of the pulse laser beam. This can also suppress adhesion, to surfaces of the beam splitter 22, the output coupling mirror OC1, and the window 33 located in a gas flow path, of impurities due to outgassing from components or the like. This can suppress reductions in transmittance and polarization properties of the optical elements such as the window 33 due to the adhesion of impurities, and reduce exchange frequency of the optical elements.

A pipe having an exhaust valve EV2 is connected to the optical path tube 52. Opening of the exhaust valve EV2 is adjusted according to a control signal from the control unit CO. The exhaust valve EV2 opens to exhaust the gas in the optical path tube 52. The connection of the pipe having the exhaust valve EV2 to the optical path tube 52 is an exhaust port EP2 that exhausts the gas in the optical path tube 52. In this example, the exhaust port EP2 is provided beside the window 34 in the optical path tube 52. The purge gas supplied through the gas supply port SP2 is mixed with the gas in the casing 41 and the second optical path tube 52, and flows to the exhaust port EP2. Thus, the purge gas can reduce an oxygen concentration in the casing 41 and the optical path tube 52, and the reduced oxygen concentration can be maintained. This can also suppress adhesion, to surfaces of the grating 42, the prisms 43, 44, and the window 34 located in the gas flow path, of impurities due to outgassing from components or the like.

In this example, the pipe having the exhaust valve EV1 and the pipe having the exhaust valve EV2 are connected to a different pipe, through which the gas in the optical path tube 51 and the gas in the optical path tube 52 are exhausted into the casing 10.

A laser gas supply source 62 storing a laser gas is further arranged outside the casing 10. The laser gas supply source 62 supplies a plurality of gases used as the laser gas. In this example, the laser gas supply source 62 supplies, for example, a mixed gas containing F₂, Ar, and Ne. In the case of a KrF excimer laser, the laser gas supply source 62 supplies, for example, a mixed gas containing F₂, Kr, and Ne. A pipe is connected to the laser gas supply source 62 and extends into the casing 10. The pipe is connected to a laser gas supply device 63. The laser gas supply device 63 has a valve or a flow regulating valve (not shown), and a different pipe connected to the chamber 30 is connected to the laser gas supply device 63. The laser gas supply device 63 uses the gases as the laser gas according to a control signal from the control unit CO, and supplies the laser gas through the different pipe into the chamber 30. The connection of the different pipe to the chamber 30 is a laser gas supply port LSP1 that supplies the laser gas into the chamber 30.

An exhaust device 64 is arranged in the casing 10. The exhaust device 64 is connected to the chamber 30 by a pipe. The exhaust device 64 exhausts the gas in the chamber 30 through the pipe into the casing 10. In this case, the exhaust device 64 adjusts an exhaust amount or the like according to a control signal from the control unit CO, and removes an F₂ gas from the gas exhausted from the chamber 30 using a halogen filter (not shown). The connection of the pipe to the chamber 30 is a laser gas exhaust port LEP1 that exhausts the gas from the chamber 30.

The casing 10 has an exhaust duct 11. The gas in the casing 10 is exhausted through the exhaust duct 11 to the outside of the casing 10. Thus, the gas in the chamber 30 exhausted from the exhaust device 64 into the casing 10, and the gas in the optical path tube 51 and the optical path tube 52 exhausted through the exhaust port EP1 and the exhaust port EP2 into the casing 10 are exhausted through the exhaust duct 11 to the outside of the casing 10.

2.2 Operation

Next, an operation of the gas laser apparatus 100 of the comparative example will be described.

In introduction or maintenance of the gas laser apparatus 100, for example, air flows into the optical path tubes 51, 52. In this state, the control unit CO closes the exhaust valves EV1, EV2. Further, the control unit CO closes the gas supply valves SV0 to SV2. Thus, no purge gas is supplied into the optical path tubes 51, 52, and no gas is exhausted through the optical path tubes 51, 52.

Then, the control unit CO opens the exhaust valves EV1, EV2. At this time, no purge gas has been supplied, and thus the gas in the optical path tube 51, the casing 21, and the optical path tube 53, and the gas in the optical path tube 52 and the casing 41 are not exhausted.

Then, the control unit CO opens the gas supply valves SV0 to SV2. Thus, the purge gas is supplied through the gas supply port SP1 into the casing 21, and the purge gas is supplied through the gas supply port SP2 into the casing 41. Since the exhaust valve EV1 has been opened, the gas in the optical path tube 51, the casing 21, and the optical path tube 53 is pushed out by the purge gas and exhausted through the exhaust port EP1 through the pipe into the casing 10. Thus, the purge gas reduces the oxygen concentration in the casing 21, the first optical path tube 51, and the optical path tube 53, and the reduced oxygen concentration is maintained. Also, the gas flows on the surfaces of the beam splitter 22, the output coupling mirror OC1, and the window 33, thereby suppressing adhesion of impurities or the like to the surfaces. Since the exhaust valve EV2 has been also opened, the gas in the optical path tube 52 and the casing 41 is pushed out by the purge gas and exhausted through the exhaust port EP2 into the casing 10. Thus, the purge gas reduces the oxygen concentration in the casing 41 and the second optical path tube 52, and the reduced oxygen concentration is maintained. The gas flows on the surfaces of the grating 42, the prisms 43, 44, and the window 34, thereby suppressing adhesion of impurities or the like to the surfaces. The gas exhausted into the casing 10 is exhausted through the exhaust duct 11 to the outside of the casing 10.

Then, the control unit CO maintains this state for a predetermined period. This period is, for example, 5 to 10 minutes. In this period, the oxygen concentration in the optical path tube 51, the casing 21, and the optical path tube 53 reaches a predetermined concentration or lower, and the oxygen concentration in the optical path tube 52 and the casing 41 reaches a predetermined concentration or lower.

Before completion of this period, the control unit CO causes the laser gas to be supplied into the chamber 30 and causes the supplied laser gas to be circulated. Specifically, the control unit CO controls the exhaust device 64 to exhaust the gas in the chamber 30 through the laser gas exhaust port LEP1 into the casing 10. Then, a predetermined amount of laser gas is supplied through the laser gas supply port LSP1. As a result, the laser gas fills the chamber 30. The control unit CO also controls the motor 39 to rotate the cross flow fan 38. The cross flow fan 38 rotates to circulate the laser gas. Frictional heat or the like caused by circulation of the laser gas increases a temperature in the chamber 30. The temperature in the chamber reaches, for example, about 65° C.

Then, the control unit CO causes the laser beam to be emitted. First, the control unit CO controls the motor 39 to maintain circulation of the laser gas in the chamber 30. The control unit CO also controls the charger 35 and the switch in the pulse power module 36 to apply a high voltage between the electrodes 31, 32. When the high voltage is applied between the electrodes 31, 32, insulation between the electrodes 31, 32 is broken to cause discharge. By energy of the discharge, the laser medium contained in the laser gas between the electrodes 31, 32 is excited to cause spontaneous emission when returning to the ground state. Part of the light is emitted through the window 34, and reflected by the grating 42 through the prisms 43, 44. The light reflected by the grating 42 and again propagating through the window 34 into the chamber 30 is line narrowed. With the line narrowed light, the excited laser medium causes stimulated emission to amplify the light. Then, the light having a predetermined wavelength resonates between the grating 42 and the output coupling mirror OC1 to cause laser oscillation. Then, part of the laser beam passes through the output coupling mirror OC1 and is emitted through the laser beam exit window OW.

At this time, the laser beam reflected by the beam splitter 22 is received by the pulse energy sensor 23, and the pulse energy sensor 23 outputs, to the control unit CO, a signal according to intensity of energy of the received laser beam. The control unit CO controls the charger 35 and the pulse power module 36 based on the signal, and adjusts power of the emitted laser beam.

The purge gas is supplied through the gas supply ports SP1, SP2 also during emission of the laser beam. Thus, the gas flowing through the optical path tube 51, the casing 21, and the optical path tube 53 maintains the oxygen concentration in the optical path tube 51, the casing 21, and the optical path tube 53 at the predetermined concentration or lower. The gas flowing through the optical path tube 52 and the casing 41 maintains the oxygen concentration in the optical path tube 52 and the casing 41 at the predetermined concentration or lower.

2.3 Problem

As described above, when the laser beam oscillates or stops, the purge gas is supplied and thus the gas in the optical path tubes 51, 52 flows on the surfaces of the windows 33, 34. Temperatures of the gases are substantially the same as that of the purge gas. As described above, the temperature in the chamber 30 becomes higher than that of the purge gas due to frictional heat or the like caused by circulation of the laser gas. Thus, the surfaces of the windows 33, 34 opposite to the chamber 30 are cooled by the gases flowing on the surfaces, and become low in temperature than the surfaces of the windows 33, 34 on the side of the chamber 30. Then, when the laser beam is emitted, the windows 33, 34 are heated by energy of the laser beam. Thus, there is a concern that at start and stop of laser oscillation, a rapid temperature difference occurs between the surfaces of the windows 33, 34 on the side of the chamber 30 and the surfaces on the opposite side, and the windows 33, 34 are damaged by a thermal shock, thereby reducing durability of the gas laser apparatus 100.

Thus, embodiments below exemplify a gas laser apparatus with high durability.

### 3. Description of Gas Laser Apparatus of Embodiment 1

Next, a configuration of a gas laser apparatus of Embodiment 1 will be described. The same components as those described above are denoted by the same reference numerals, and overlapping descriptions are omitted unless otherwise stated.

3.1 Configuration

FIG. 3 is a schematic diagram of an exemplary configuration of the entire gas laser apparatus of this embodiment. As shown in FIG. 3, a gas laser apparatus 100 of this embodiment is mainly different from the gas laser apparatus 100 of the comparative example in including gas heating units HT1, HT2, gas supply valves SV3, SV4, and gas supply ports SP3, SP4.

FIG. 4 shows a configuration of a section from one window 33 provided in a chamber 30 to a laser beam exit window OW provided in a casing 10. As shown in FIGS. 3 and 4, a different pipe branches off from a pipe connecting a purge gas manifold PM and a gas supply valve SV1, and the gas heating unit HT1 is connected to the branch pipe. The gas heating unit HT1 includes, for example, a heater such as an electric heater or a ceramic heater, and heats a purge gas flowing through the pipe. Specifically, the heater may heat the pipe to heat the purge gas flowing through the pipe or the heater may have a sealed configuration such that the purge gas is released into the heater and heated. Part of components that constitute the heater, such as a radiating fin, may enter the pipe to heat the purge gas. When a heat exchanger is arranged in the casing 10, the gas heating unit HT1 may use part of the heat exchanger. The gas heating unit HT1 may include a heater different from the heaters exemplified above. A temperature of the gas heating unit HT1 is adjusted according to a control signal from a control unit CO. Thus, a temperature of the purge gas heated by the gas heating unit HT1 is adjusted according to the control signal from the control unit CO.

A pipe having a gas supply valve SV3 is connected to the gas heating unit HT1. Opening of the gas supply valve SV3 is adjusted according to a control signal from the control unit CO. The pipe having the gas supply valve SV3 is connected to an optical path tube 51, and the connection of the pipe to the optical path tube 51 is a gas supply port SP3 that supplies the purge gas into the optical path tube 51. Thus, the gas supply port SP3 supplies the purge gas heated by the gas heating unit HT1. Thus, the gas supply port SP3 is a heated gas supply port that supplies the heated purge gas.

The gas supply port SP3 is provided beside the window 33 to be directed to the window 33 in the optical path tube 51. The gas supply port SP3 may be formed to face any of surfaces of the window 33. Any of surfaces in this case is not a surface in contact with the inside of a chamber 30. The same applies to descriptions of other windows hereinafter. Specifically, the gas supply port SP3 is provided in such a position that the purge gas is blown on an area of the window 33 closer to the chamber 30. Thus, an area of the window 33 closest to the gas supply port SP3 is the area closer to the chamber 30. The area closer to the chamber 30 is part of an area of the window 33 close to the chamber 30, the window 33 being tilted with respect to a traveling direction of a laser beam. Further, the area closer to the chamber 30 is part of an area close to an electrode 31 or 32 in the chamber 30. The same applies to descriptions of other windows hereinafter. A temperature of the purge gas supplied through the gas supply port SP3 is higher than a temperature in the chamber 30. If the temperature in the chamber 30 is, for example, about 65° C. as described above, the temperature of the purge gas supplied through the gas supply port SP3 and blown on the window 33 is preferably, for example, 80° C. to 100° C. With such a temperature, a temperature on the side of the window 33 opposite to the chamber 30, that is, a temperature on the side on which the purge gas is blown is close to the temperature in the chamber 30. This can reduce a difference in temperature between opposite surfaces of the window 33.

An exhaust port EP1 in this embodiment is provided between an output coupling mirror OC1 as an optical element and the gas supply port SP3 when viewed perpendicularly to the traveling direction of the laser beam emitted through the window 33. This suppresses the purge gas supplied through the gas supply port SP3 from flowing toward the output coupling mirror OC1 as compared to the case where the exhaust port EP1 is provided on the side of the output coupling mirror OC1 opposite to the gas supply port SP3. The exhaust port EP1 is provided in such a position that the purge gas supplied through the gas supply port SP3 can easily flow along the surface of the window 33. Specifically, the exhaust port EP1 is provided in the optical path tube 51 on the opposite side to the gas supply port SP3 in a radial direction and near the area of the window 33 on the opposite side to the chamber 30, not the area on the chamber 30 side.

Since no gas heating unit is connected to a pipe connected to a gas supply port SP1, the gas supply port SP1 supplies an unheated purge gas. Thus, the gas supply port SP1 is an unheated gas supply port that supplies the unheated purge gas. The gas supply port SP1 in this embodiment is provided in a position similar to that of the gas supply port SP1 in the comparative example, and is thus provided on the side of the output coupling mirror OC1 as the optical element opposite to the exhaust port EP1.

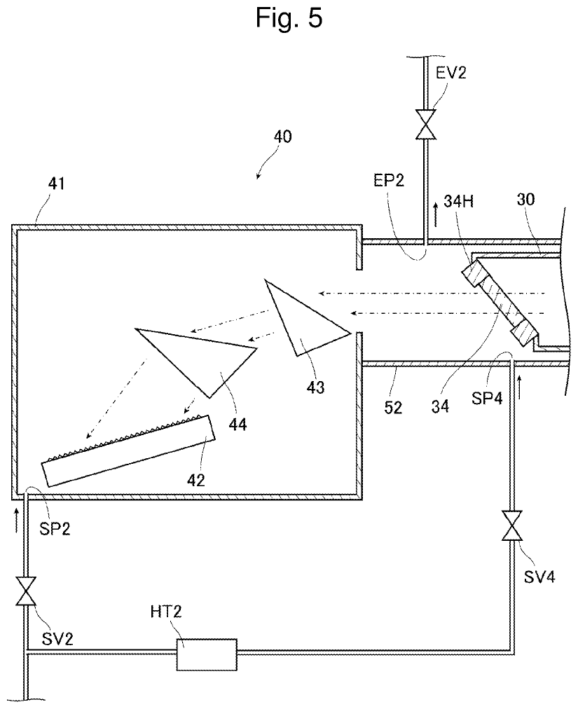

FIG. 5 shows a configuration of a section from the other window 34 provided in the chamber 30 to a line narrowing module 40. As shown in FIGS. 3 and 5, a different pipe branches off from a pipe connecting the purge gas manifold PM and a gas supply valve SV2, and a gas heating unit HT2 is connected to the branch pipe. The gas heating unit HT2 has a configuration similar to that of the gas heating unit HT1. Thus, the gas heating unit HT2 heats the purge gas flowing through the pipe. The gas heating unit HT1 and the gas heating unit HT2 may be integrally formed. A temperature of the gas heating unit HT2 is adjusted according to a control signal from the control unit CO. Thus, a temperature of the purge gas heated by the gas heating unit HT2 is adjusted according to the control signal from the control unit CO.

A pipe having a gas supply valve SV4 is connected to the gas heating unit HT2. Opening of the gas supply valve SV4 is adjusted according to a control signal from the control unit CO. The pipe having the gas supply valve SV4 is connected to an optical path tube 52, and the connection of the pipe to the optical path tube 52 is a gas supply port SP4 that supplies the purge gas into the optical path tube 52. Thus, the gas supply port SP4 supplies the purge gas heated by the gas heating unit HT2. Thus, the gas supply port SP4 is a heated gas supply port that supplies the heated purge gas.

The gas supply port SP4 is provided beside a window 34 to be directed to the window 34 in the optical path tube 52. The gas supply port SP4 may be formed to face any of surfaces of the window 34. Specifically, the gas supply port SP4 is provided in such a position that the purge gas is blown on an area of the window 34 closer to the chamber 30. Thus, an area of the window 34 closest to the gas supply port SP4 is the area closer to the chamber 30. A temperature of the purge gas supplied through the gas supply port SP4 is similar to that of the purge gas supplied through the gas supply port SP3. Thus, the purge gas is blown through the gas supply port SP4 to reduce a difference in temperature between opposite surfaces of the window 34.

An exhaust port EP2 in this embodiment is provided between a prism 43 as an optical element and the gas supply port SP4 when viewed perpendicularly to the traveling direction of the laser beam emitted through the window 34. This suppresses the purge gas supplied through the gas supply port SP4 from flowing toward the prism 43 as compared to the case where the exhaust port EP2 is provided on the side of the prism 43 opposite to the gas supply port SP4. The exhaust port EP2 is provided in such a position that the purge gas supplied through the gas supply port SP4 can easily flow along the surface of the window 34. Specifically, the exhaust port EP2 is provided in the optical path tube 52 on the opposite side to the gas supply port SP4 in a radial direction and near the area of the window 34 on the opposite side to the chamber 30, not the area on the chamber 30 side.

Since no gas heating unit is connected to a pipe connected to a gas supply port SP2, the gas supply port SP2 supplies an unheated purge gas. Thus, the gas supply port SP2 is an unheated gas supply port that supplies the unheated purge gas. The gas supply port SP2 in this embodiment is provided in a position similar to that of the gas supply port SP2 in the comparative example, and is thus provided on the side of at least part of a grating 42 and prisms 43, 44 as optical elements opposite to the exhaust port EP2.

3.2 Operation

Next, an operation of the gas laser apparatus 100 of this embodiment will be described.

In the gas laser apparatus 100 of this embodiment, as in the gas laser apparatus 100 of the comparative example, the control unit CO closes exhaust valves EV1, EV2 with air having flowed into the optical path tubes 51, 52. Further, the control unit CO closes the gas supply valves SV0 to SV4. Thus, no purge gas is supplied into the optical path tubes 51, 52, and no gas is exhausted through the optical path tubes 51, 52.

Then, the control unit CO opens the exhaust valves EV1, EV2. At this time, no purge gas has been supplied, and thus the gas in the optical path tube 51, a casing 21, and an optical path tube 53, and the gas in the optical path tube 52 and a casing 41 are not exhausted. The control unit CO controls the gas heating units HT1, HT2 to heat the purge gas in the pipe.

Then, the control unit CO opens the gas supply valves SV0 to SV4. The unheated purge gas is supplied through the gas supply ports SP1, SP2 into the casings 21, 41, and the heated purge gas is supplied through the gas supply ports SP3, SP4 into the optical path tubes 51, 52. Thus, the windows 33, 34 are heated by the purge gas supplied through the gas supply ports SP3, SP4.

As described above, since the exhaust valve EV1 has been opened, the gas in the optical path tube 51, the casing 21, and the optical path tube 53 is pushed out by the purge gas and exhausted through the exhaust port EP1 through the pipe into the casing 10. Thus, as in the comparative example, the purge gas reduces an oxygen concentration in the casing 21, the first optical path tube 51, and the optical path tube 53, and the reduced oxygen concentration is maintained. Also, the gas flows on surfaces of a beam splitter 22, the output coupling mirror OC1, and the window 33, thereby suppressing adhesion of impurities or the like to the surfaces. At this time, the output coupling mirror OC1 is located between the gas supply port SP1 and the exhaust port EP1, and thus the unheated purge gas mainly flows around the output coupling mirror OC1 to suppress heating of the output coupling mirror OC1.

Since the exhaust valve EV2 has been also opened, the gas in the optical path tube 52 and the casing 41 is pushed out by the purge gas and exhausted through the exhaust port EP2 through the pipe into the casing 10. Thus, as in the comparative example, the purge gas reduces an oxygen concentration in the casing 41 and the optical path tube 52, and the reduced oxygen concentration is maintained. The gas flows on surfaces of the grating 42, the prisms 43, 44, and the window 34, thereby suppressing adhesion of impurities or the like to the surfaces. At this time, at least part of the grating 42 and the prisms 43, 44 as the optical elements are located between the gas supply port SP2 and the exhaust port EP2, and thus the unheated purge gas mainly flows around the optical elements to suppress heating of the optical elements.

The gas exhausted into the casing 10 is exhausted through an exhaust duct 11 to the outside of the casing 10.

Then, the control unit CO maintains this state for a predetermined period as in the comparative example. In this period, the oxygen concentration in the optical path tube 51, the casing 21, and the optical path tube 53 reaches a predetermined concentration or lower, and the oxygen concentration in the optical path tube 52 and the casing 41 reaches a predetermined concentration or lower.

Before completion of this period, the control unit CO causes the laser gas to be supplied into the chamber 30 and causes the supplied laser gas to be circulated as in the comparative example.

Then, the control unit CO causes the laser beam to be emitted as in the comparative example.

3.3 Effect

The gas laser apparatus of this embodiment includes the gas supply ports SP3, SP4 as the heated gas supply ports that supply the heated purge gas into closed spaces including spaces in the optical path tubes 51, 52. Thus, the surfaces of the windows 33, 34 exposed inside the optical path tubes 51, 52 can be heated by the purge gas supplied through the gas supply ports SP3, SP4. Thus, when the laser beam is emitted, a difference between the temperatures of the windows 33, 34 on the side of the chamber 30 and the temperatures thereof on the side of the optical path tubes 51, 52 becomes smaller than that in the comparative example. Thus, with the gas laser apparatus 100 of this embodiment, even if the windows 33, 34 are heated when the laser beam is emitted, a smaller thermal shock can be applied on the windows 33, 34 than in the gas laser apparatus 100 of the comparative example. Also, even if the temperatures of the windows 33, 34 decrease when the emission of the laser beam is stopped, a smaller thermal shock can be applied on the windows 33, 34 than in the gas laser apparatus 100 of the comparative example. Thus, the gas laser apparatus of this embodiment can have high durability.

In the gas laser apparatus 100 of this embodiment, the gas supply ports SP3, SP4 are provided in the positions such that the purge gas is blown on the windows 33, 34. Thus, the windows 33, 34 can be efficiently heated. The gas supply ports SP3, SP4 need not be provided in the positions such that the purge gas is blown on the windows 33, 34. In this case, the purge gas supplied through the gas supply ports SP3, SP4 into the closed spaces increases temperatures in the closed spaces to heat the windows 33, 34.

In the gas laser apparatus 100 of this embodiment, the windows 33, 34 are tilted with respect to the traveling direction of the laser beam, and the gas supply ports SP3, SP4 are provided in the positions such that the purge gas is blown on the areas of the windows 33, 34 closer to the chamber 30. With such a configuration, the purge gas can easily flow on the surfaces of the windows 33, 34 and can more efficiently heat the windows 33, 34.

In the gas laser apparatus 100 of this embodiment, the exhaust port EP1 is provided between the gas supply port SP3 and the output coupling mirror OC1 as the optical element when viewed perpendicularly to the traveling direction of the laser beam emitted through the window 33. The exhaust port EP2 is provided between the gas supply port SP4 and the prism 43 as the optical element when viewed perpendicularly to the traveling direction of the laser beam emitted through the window 34. This can suppress the heated purge gas supplied through the gas supply ports SP3, SP4 from flowing around the optical elements as compared to the case where the exhaust ports EP1, EP2 are provided on the sides of the optical elements opposite to the gas supply ports SP3, SP4. This can suppress changes in properties of the laser beam due to an increase in temperature of the optical elements. Further, the gas laser apparatus 100 of this embodiment includes the gas supply ports SP1, SP2 that are provided on the sides of the optical elements opposite to the exhaust ports EP1, EP2 and supply the unheated purge gas into the closed spaces. Thus, the unheated purge gas rather than the heated purge gas can flow around the optical elements. This further suppresses the increase in temperature of the optical elements. If the increase in temperature of the optical elements is acceptable, the exhaust ports EP1, EP2 may be provided on the sides of the optical elements opposite to the gas supply ports SP3, SP4. In this case, the gas supply ports SP1, SP2 may be provided closer to the exhaust ports EP1, EP2 than the optical elements, or no gas supply ports SP1, SP2 may be provided and no unheated purge gas may be supplied.

In the gas laser apparatus 100 of this embodiment, the temperature of the purge gas is higher than the temperature in the chamber 30. This can suppress changes in temperature of the windows 33, 34 when the laser beam is emitted as compared to the case where the temperature of the purge gas is lower than the temperature in the chamber 30. The purge gas supplied through the gas supply ports SP3, SP4 needs only be heated, and the temperature of the purge gas needs not be higher than the temperature in the chamber 30.

As long as the purge gas is supplied into each of the closed space including the space in the optical path tube 51 and the closed space including the space in the optical path tube 52, the heated purge gas may be supplied into one closed space and no heated purge gas may be supplied into the other closed space. In this case, the heated purge gas is preferably supplied into the closed space including the space in the optical path tube 51 because power of the laser beam emitted thorough the window 33 is higher than power of the laser beam emitted through the window 34.

In this embodiment, the gas supply valves SV1 to SV4 are opened at the same timing, but for example, the timing when the gas supply valves SV1, SV2 are opened may be different from the timing when the gas supply valves SV3, SV4 are opened. In at least part of a period when the laser beam is emitted, the gas supply valves SV3, SV4 are opened, and the heated purge gas is supplied through the gas supply ports SP3, SP4.

### 4. Description of Gas Laser Apparatus of Embodiment 2

Next, a gas laser apparatus of Embodiment 2 will be described. The same components as those described above are denoted by the same reference numerals, and overlapping descriptions are omitted unless otherwise stated.

4.1 Configuration

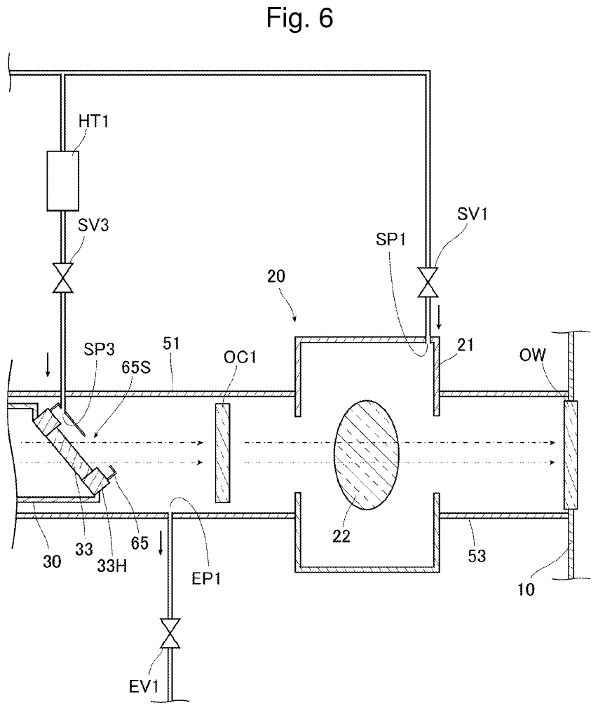

FIG. 6 shows a configuration of a section from one window 33 provided in the chamber 30 to the laser beam exit window OW provided in the casing 10 in the gas laser apparatus of this embodiment. As shown in FIG. 6, the gas laser apparatus of this embodiment is different from the gas laser apparatus 100 of Embodiment 1 in including a window cover 65. The window cover 65 covers the window 33 in the optical path tube 51 and has a slit 65S through which the laser beam passes. The slit 65S preferably has a shape substantially similar to a sectional shape of the laser beam passing through the slit 65S when viewed along the laser beam emitted through the window 33 such that the slit 65S has no unnecessary region.

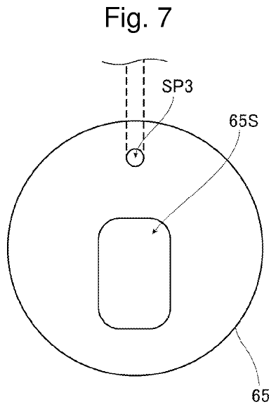

FIG. 7 is a front view of the window cover 65. As shown in FIGS. 6 and 7, the pipe having the gas supply valve SV3 in this embodiment is connected to the window cover 65. In FIG. 7, the pipe is shown by a broken line. In this embodiment, the connection of the pipe having the gas supply valve SV3 to the window cover 65 is a gas supply port SP3 that supplies the heated purge gas between the window 33 and the window cover 65. The window cover 65 is preferably made of, for example, metal to facilitate formation of the window cover 65, and examples of the metal may include, for example, aluminum and stainless steel. However, the window cover 65 is preferably made of a thermal insulation material to suppress a reduction in temperature of the purge gas supplied between the window 33 and the window cover 65. “Thermal insulation” herein refers to having lower thermal conductivity than metal. Examples of the thermal insulation material may include ceramic and glass.

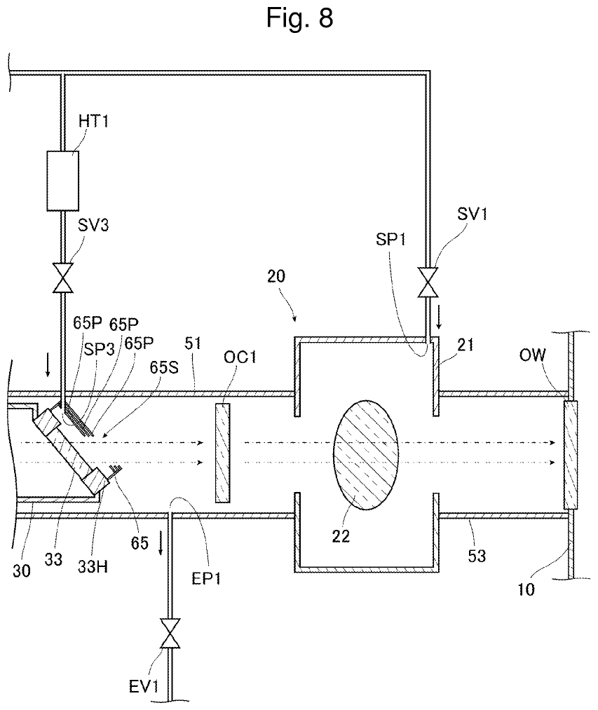

In the example in FIG. 6, the window cover 65 is formed of one plate-like member. However, the window cover 65 is not limited to such a configuration. FIG. 8 shows a variant of the window cover 65. As shown in FIG. 8, the window cover 65 of this variant has a multilayer structure including a plurality of cover members 65P arranged at intervals. The window cover 65 of this variant is preferable because it can suppress a reduction in temperature of the purge gas supplied between the window 33 and the window cover 65. The window cover 65 of this variant is also preferable because the purge gas supplied between the window 33 and the window cover 65 is more easily retained than with the window cover 65 in FIG. 6.

Although not shown, the window 34 may be covered with a window cover similar to the window cover 65 in this embodiment. In this case, a gas supply port SP4 is provided in the window cover that covers the window 34, and supplies the heated purge gas between the window 34 and the window cover that covers the window 34.

4.2 Effect

In the gas laser apparatus 100 of this embodiment, the window cover covers the window 33 in the optical path tube 51, and the gas supply port SP3 is provided in such a position that the purge gas is supplied between the window 33 and the window cover 65. This can efficiently heat the window 33. The window cover 65 formed of a thermal insulation member can more efficiently heat the window 33. As shown in FIG. 8, the window cover 65 having the multilayer structure including the cover members 65P arranged at intervals can further efficiently heat the window 33.

### 5. Description of Gas Laser Apparatus of Embodiment 3

Next, a gas laser apparatus of Embodiment 3 will be described. The same components as those described above are denoted by the same reference numerals, and overlapping descriptions are omitted unless otherwise stated.

5.1 Configuration

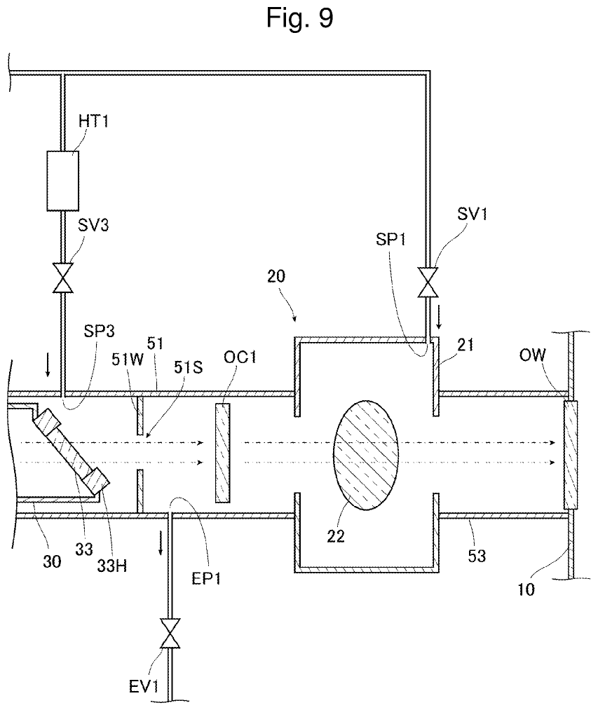

FIG. 9 shows a configuration of a section from one window 33 provided in the chamber 30 to the laser beam exit window OW provided in the casing 10 in the gas laser apparatus of this embodiment. As shown in FIG. 9, the gas laser apparatus of this embodiment is different from the gas laser apparatus of Embodiment 1 in including a wall 51W.

The wall 51W is provided between the window 33 and the output coupling mirror OC1 as the optical element in the optical path tube 51 and closes the optical path tube 51. The wall 51W has a slit 51S. The slit 51S is formed such that the laser beam propagating between the window 33 and the output coupling mirror OC1 can pass through the slit 51S. The slit 51S preferably has a shape substantially similar to a sectional shape of the laser beam passing through the slit 51S such that the slit 51S has no unnecessary region. The wall 51W is preferably made of, for example, metal to prevent outgassing, and examples of the metal may include, for example, aluminum and stainless steel. However, the wall 51W is preferably made of a thermal insulation material such as ceramic or glass to suppress a reduction in temperature of the purge gas supplied between the window 33 and the wall 51W.

The gas supply port SP3 is provided in a position similar to that of the gas supply port SP3 in Embodiment 1. Thus, the heated purge gas is supplied between the window 33 and the wall 51W.

In this embodiment, the exhaust port EP1 is provided between the wall 51W and the output coupling mirror OC1 as the optical element. Thus, the gas between the window 33 and the wall 51W flows through the slit 51S and is exhausted through the exhaust port EP1.

Although not shown, a wall similar to the wall 51W in this embodiment may be provided in the optical path tube 52. In this case, the wall provided in the optical path tube 52 is provided between the window 34 and the prism 43 as the optical element, and the gas supply port SP4 is provided closer to the window 34 than the wall provided in the optical path tube 52. The exhaust port EP2 is preferably provided between the wall provided in the optical path tube 52 and the prism 43.

5.2 Effect

In the gas laser apparatus of this embodiment, the wall 51W is provided in a position between the window 33 and the output coupling mirror OC1 as the optical element in the optical path tube 51, and the gas supply port SP3 is provided closer to the window 33 than the wall 51W. Thus, the wall 51W serves as a barrier to allow the heated purge gas to be more easily retained between the window 33 and the wall 51W than in the gas laser apparatus 100 of Embodiment 1. This can more efficiently heat the window 33 than in the gas laser apparatus 100 of Embodiment 1.

In this embodiment, the exhaust port EP1 is provided between the wall 51W and the output coupling mirror OC1. This can more efficiently heat the window 33 than in the case where the exhaust port EP1 is provided between the window 33 and the wall 51W. The exhaust port EP1 may be provided between the window 33 and the wall 51W.

### 6. Description of Gas Laser Apparatus of Embodiment 4

Next, a gas laser apparatus of Embodiment 4 will be described. The same components as those described above are denoted by the same reference numerals, and overlapping descriptions are omitted unless otherwise stated.

6.1 Configuration

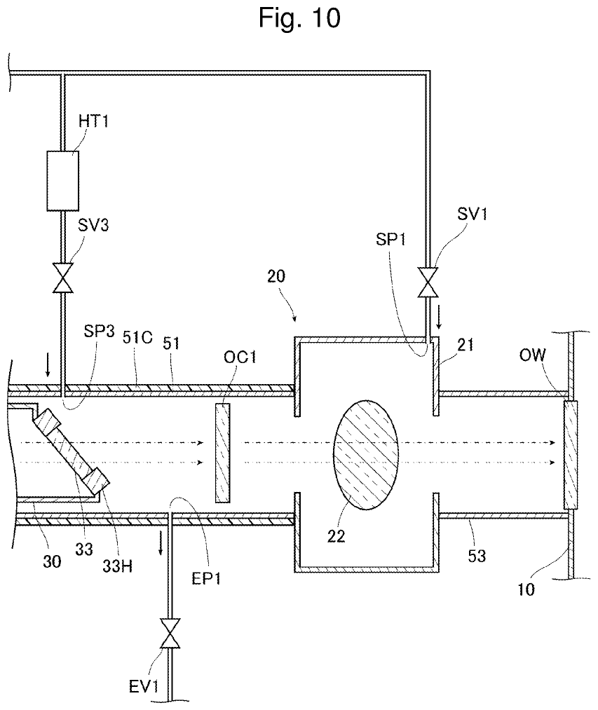

FIG. 10 shows a configuration of a section from one window 33 provided in the chamber 30 to the laser beam exit window OW provided in the casing 10 in the gas laser apparatus of this embodiment. As shown in FIG. 10, the gas laser apparatus of this embodiment is different from the gas laser apparatus of Embodiment 1 in that the optical path tube 51 is covered with a cover member 51C. The cover member 51C is a thermal insulation layer and made of, for example, resin, foam metal, glass, aerogel, or the like. Although not shown, the optical path tube 52 may be covered with a cover member similar to the cover member 51C.

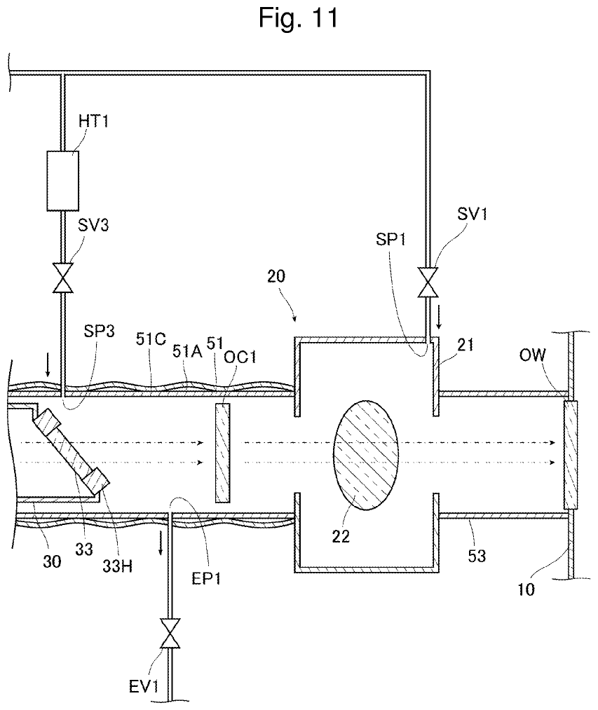

FIG. 11 shows a variant of the gas laser apparatus of this embodiment. As shown in FIG. 11, this variant is different from the example in FIG. 10 in that an air layer 51A is provided between the optical path tube 51 and the cover member 51C. The air layer 51A is preferably reduced in pressure to improve thermal insulation. In this variant, the air layer 51A is a thermal insulation layer, and thus the cover member 51C needs not be thermally insulating. Although not shown, the optical path tube 52 may be covered with a cover member similar to the cover member 51C of this example via an air layer.

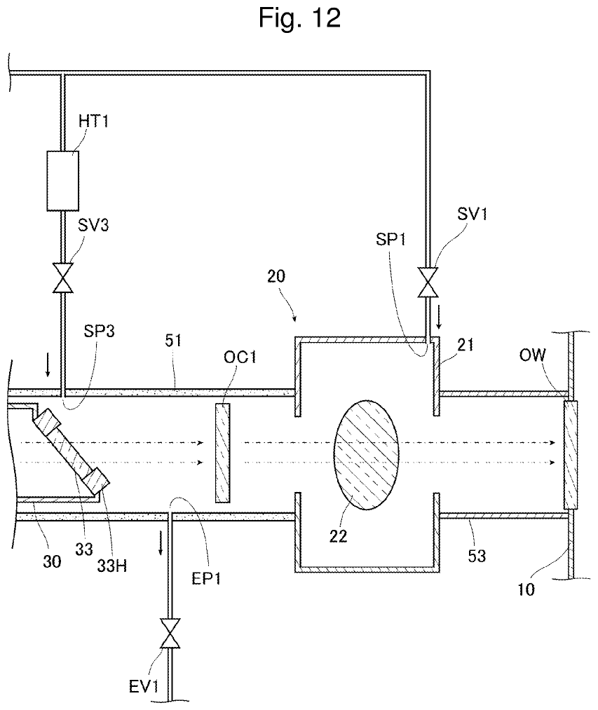

FIG. 12 shows another variant of the gas laser apparatus of this embodiment. As shown in FIG. 12, this variant is different from the gas laser apparatus of Embodiment 1 and the example in FIG. 10 in that the optical path tube 51 is made of a thermal insulation material. Examples of such a material may include ceramic and glass. Although not shown, the optical path tube 52 may be made of a thermal insulation material.

6.2 Effect

In the gas laser apparatus of this embodiment, an outer peripheral surface of the optical path tube 51 is covered with the thermal insulation layer as described with reference to FIGS. 10 and 11, or the optical path tube 51 is made of the thermal insulation material as described with reference to FIG. 12. This can suppress a reduction in temperature of the heated purge gas supplied through the gas supply port SP3. This can efficiently heat the window 33.

In this embodiment, the example has been shown in which the entire outer peripheral surface of the optical path tube 51 is covered with the thermal insulation layer or the entire optical path tube 51 is made of the thermal insulation material. However, as long as at least part of the outer peripheral surface of the optical path tube 51 is covered with the thermal insulation layer or at least part of the optical path tube 51 is made of the thermal insulation material, the reduction in temperature of the purge gas can be suppressed and the window 33 can be efficiently heated. For example, the outer peripheral surface of the optical path tube 51 in a position with the gas supply port SP3 may be covered with the thermal insulation layer, and the outer peripheral surface of the optical path tube 51 closer to the output coupling mirror OC1 than the exhaust port EP1 may not be covered with the thermal insulation layer. The optical path tube 51 in the position with the gas supply port SP3 may be made of the thermal insulation material, and the optical path tube 51 in the position closer to the output coupling mirror OC1 than the exhaust port EP1 may be made of a material other than the thermal insulation material.

### 7. Description of Gas Laser Apparatus of Embodiment 5

Next, a gas laser apparatus of Embodiment 5 will be described. The same components as those described above are denoted by the same reference numerals, and overlapping descriptions are omitted unless otherwise stated.

7.1 Configuration

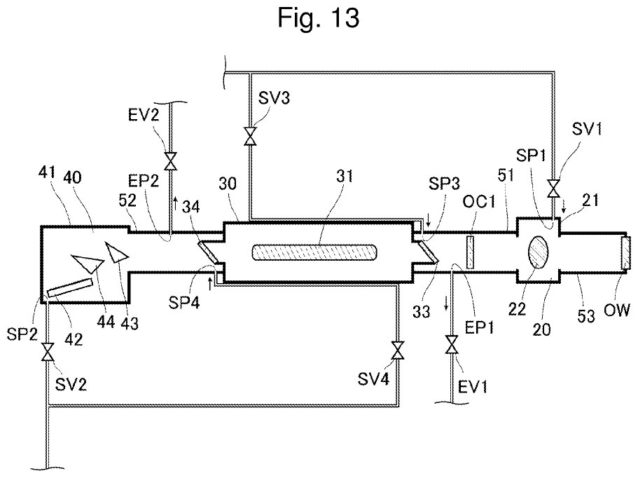

FIG. 13 is a schematic diagram of a configuration of essential portions of the gas laser apparatus of this embodiment. Unlike in FIG. 3, the essential portions of the gas laser apparatus are shown in an overlapping direction of the electrodes 31, 32. As shown in FIG. 13, the gas laser apparatus of this embodiment is different from the gas laser apparatus 100 of Embodiment 1 in that the gas heating units HT1, HT2 are not provided and part of the pipes having the gas supply valves SV3, SV4 extend on an outer surface of the chamber 30. As shown in FIG. 13, part of the pipes having the gas supply valves SV3, SV4 are arranged in contact with the outer surface of the chamber 30.

As described above, the chamber 30 is made of metal, and the temperature in the chamber 30 is, for example, about 65° C. A temperature of the outer surface of the chamber 30 is slightly lower than the temperature in the chamber 30. The chamber 30 heats each pipe extending on the outer surface of the chamber 30, and the pipe is heated to heat the purge gas flowing through the pipe. Thus, the pipe is preferably made of metal because of its high thermal conductivity. The pipe is preferably formed serpentinely on the outer surface of the chamber 30. As such, heat may be efficiently transferred from the outer surface of the chamber 30 to part of the pipe.

For example, the chamber 30 may have grooves, and part of the pipes having the gas supply valves SV3, SV4 may be arranged in the grooves such that the pipes extend on the outer surface of the chamber 30. Although not shown, a wall of the chamber 30 may have holes, which may be part of the pipes having the gas supply valve SV3, SV4. In this case, the chamber 30 also serves as part of the pipes. Although not shown, part of the pipes having the gas supply valves SV3, SV4 may pass through the chamber 30. This can more efficiently heat the purge gas flowing through the pipes. The pipes may have a configuration to satisfactorily transfer heat and be secured on the outer surface of the chamber 30. As such, the pipes and the outer surface of the chamber 30 may be in thermal contact via a different member.

7.2 Effect

In the gas laser apparatus 100 of this embodiment, the chamber 30 heats part of the pipes through which the purge gas to be supplied to the gas supply ports SP3, SP4 flows. Heat generated by the chamber 30 by discharge is exhausted to cooling water flowing through a radiator (not shown). In other words, the gas laser apparatus 100 releases unnecessary heat generated by the chamber 30. The gas laser apparatus 100 of this embodiment can use the unnecessary heat to heat the purge gas. This can eliminate the need for a gas heating unit and reduce energy required to heat the gas.

### 8. Description of Gas Laser Apparatus of Embodiment 6

Next, a gas laser apparatus of Embodiment 6 will be described. The same components as those described above are denoted by the same reference numerals, and overlapping descriptions are omitted unless otherwise stated.

8.1 Configuration

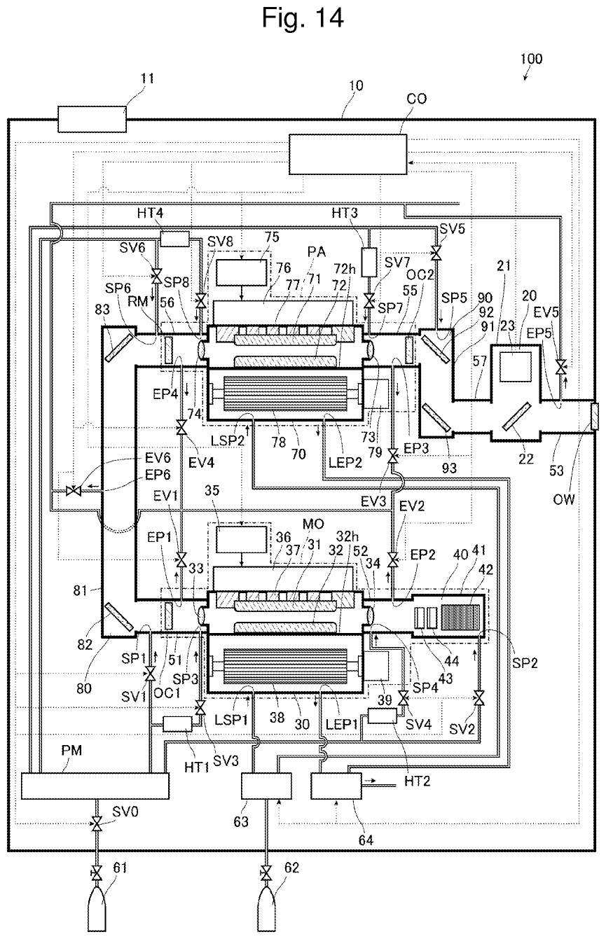

FIG. 14 is a schematic diagram of an exemplary configuration of the entire gas laser apparatus of this embodiment. As shown in FIG. 14, the gas laser apparatus 100 of this embodiment is mainly different from the gas laser apparatus 100 of Embodiment 1 in including a master oscillator MO similar to the laser oscillator LO in Embodiment 1 and further including an amplifier PA and optical transmission units 80, 90.

The amplifier PA mainly includes a chamber 70, a pair of electrodes 71, 72, an electrode holder 72h, a pair of windows 73, 74, a charger 75, a pulse power module 76, an insulating portion 77, a cross flow fan 78, a motor 79, a rear mirror RM, and an output coupling mirror OC2.

Configurations of the chamber 70, the electrodes 71, 72, the electrode holder 72h, and the insulating portion 77 in the amplifier PA are the same as those of the chamber 30, the electrodes 31, 32, the electrode holder 32h, and the insulating portion 37 in the master oscillator MO. The electrodes 71, 72 are arranged to face each other in the chamber 70. The insulating portion 77 closes an opening formed in the chamber 70, and the electrode 71 is supported by the insulating portion 77. The electrode 72 is supported by the electrode holder 72h, and the electrode holder 72h is secured to an inner surface of the chamber 70 and electrically connected to the chamber 70.

Configurations of the charger 75 and the pulse power module 76 in the amplifier PA are the same as those of the charger 35 and the pulse power module 36 in the master oscillator MO. Thus, a feedthrough of the insulating portion 77 applies a voltage supplied from the pulse power module 76 to the electrode 71. The pulse power module 76 increases a voltage applied from the charger 75 to generate a pulsed high voltage, and applies the high voltage between the electrodes 71, 72.

Configurations of the cross flow fan 78 and the motor 79 in the amplifier PA are the same as those of the cross flow fan 38 and the motor 39 in the master oscillator MO. Thus, the cross flow fan 78 is arranged in the chamber 70, and a space in which the cross flow fan 78 is arranged communicates with a space in which the electrodes 71, 72 are arranged in the chamber 70. The cross flow fan 78 rotates to circulate the laser gas filing the chamber 70 in a predetermined direction. The motor 79 is connected to the cross flow fan 78, and the motor 79 rotates to rotate the cross flow fan 78. The control unit CO can control the motor 79 to adjust a circulation speed of the laser gas circulating in the chamber 70.

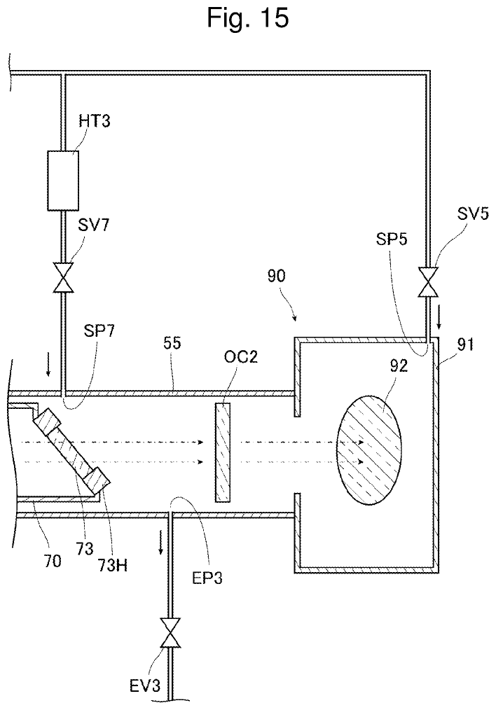

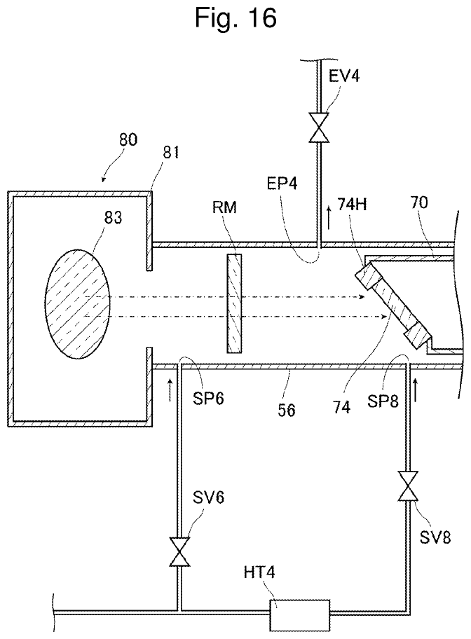

Configurations of the windows 73, 74 are the same as those of the windows 33, 34 in the master oscillator MO. Thus, the windows 73, 74 are provided to face each other with a space therebetween, the space being between the electrode 71 and the electrode 72 in the chamber 70, and tilted to form a Brewster's angle with respect to the traveling direction of the laser beam. The window 73 is provided at one end of the chamber 70 in the traveling direction of the laser beam, and the window 74 is provided at the other end of the chamber 70 in the traveling direction of the laser beam. The windows 73, 74 are secured to the chamber 70 by window holders 73H, 74H shown in FIGS. 15, 16. As described later, in the gas laser apparatus 100, the laser beam amplified in the chamber 30 is emitted through the windows 73, 74 to the outside of the chamber 70.

An optical path tube 55 having a configuration similar to that of the optical path tube 51 is connected to the one end of the chamber 70 at which the window 73 is provided. A position of the window 73 in the chamber 70 protrudes into the optical path tube 55 with a gap from an inner wall of the optical path tube 55. Thus, the window 73 is located in the optical path tube 55.

An optical path tube 56 having a configuration similar to that of the optical path tube 52 is connected to the other end of the chamber 70 at which the window 74 is provided. In other words, the optical path tube connected to the chamber 70 includes the optical path tube 55 and the optical path tube 56. A position of the window 74 in the chamber 70 protrudes into the optical path tube 56 with a gap from an inner wall of the optical path tube 56. Thus, the window 74 is located in the optical path tube 56.

A configuration of the output coupling mirror OC2 is the same as that of the output coupling mirror OC1 in the master oscillator MO. The output coupling mirror OC2 is provided on the one end side of the chamber 70, and arranged in the optical path tube 55. The output coupling mirror OC2 is an optical element that the laser beam emitted through the window 73 enters. The output coupling mirror OC2 transmits one part of the laser beam emitted through the window 73, and reflects and returns the other part through the window 73 into the chamber 70.

The rear mirror RM is provided on the other end side of the chamber 70, and arranged in the optical path tube 56. The rear mirror RM is an optical element that the laser beam emitted through the window 74 enters. The rear mirror RM reflects at least one part of the laser beam emitted through window 74 and returns the part of the laser beam through the window 74 into the chamber 70. The rear mirror RM also transmits light incident from the side opposite to the chamber 70 and causes the beam to enter the chamber 70 through the window 74. The rear mirror RM is formed of, for example, an element including a calcium fluoride substrate coated with a dielectric multilayer film.

The output coupling mirror OC2 and the rear mirror RM with the chamber 70 therebetween constitute an optical resonator, and the chamber 70 is arranged in an optical path of the optical resonator. Thus, the light entering the chamber 70 through the rear mirror RM reciprocates between the output coupling mirror OC2 and the rear mirror RM and is amplified every time it passes through a laser gain space between the electrodes 71, 72. Part of the amplified light passes through the output coupling mirror OC2, and an amplified laser beam is emitted. Examples of the amplifier PA include, for example, an injection lock amplifier.

The optical path tube 51 in the master oscillator MO is connected to the optical path tube 56 in the amplifier PA via the optical transmission unit 80. The optical transmission unit 80 includes a casing 81 and a pair of mirrors 82, 83. The connection of the casing 81 to the optical path tube 51 is open, and through the opening, a space in the casing 81 communicates with a space in the optical path tube 51. The connection of the casing 81 to the optical path tube 56 is open, and through the opening, the space in the casing 81 communicates with a space in the optical path tube 56. Thus, part of the chamber 30, the window 33, the optical path tube 51, the casing 81, the optical path tube 56, the window 74, and part of the chamber 70 form a closed space, which includes the space in the optical path tube 51 and the space in the optical path tube 56. The mirrors 82, 83 are arranged at appropriately adjusted angles in the casing 81. The laser beam emitted through the output coupling mirror OC1 in the master oscillator MO is reflected by the mirrors 82, 83 and enters the rear mirror RM in the amplifier PA. At least part of the laser beam passes through the rear mirror RM.

The optical path tube 55 in the amplifier PA is connected to the casing 21 of the energy monitor module 20 via the optical transmission unit 90 and an optical path tube 57. The optical path tube 57 is a cylindrical member made of metal. The optical transmission unit 90 includes a casing 91 and a pair of mirrors 92, 93. The connection of the casing 91 to the optical path tube 55 is open, and through the opening, a space in the casing 91 communicates with a space in the optical path tube 55. The connection of the casing 91 to the optical path tube 57 is open, and through the opening, a space in the casing 91 communicates with a space in the optical path tube 57. The casing 21 of the energy monitor module 20 is connected to the optical path tube 57. Through an opening formed in the casing 21, the space in the casing 21 communicates with the space in the optical path tube 57. As in Embodiment 1, the optical path tube 53 is connected to the casing 21 of the energy monitor module 20, and connected to the casing 10. Further, a laser beam exit window OW is provided in a position of the casing 10 surrounded by the optical path tube 53. Thus, the laser beam exit window OW, part of the casing 10, the optical path tube 53, the casing 21, the optical path tube 57, the casing 91, the optical path tube 55, part of the chamber 70, and the window 73 form a closed space, which includes the space in the optical path tube 55. The mirrors 92,93 are arranged at appropriately adjusted angles in the casing 91. The laser beam emitted through the output coupling mirror OC2 in the amplifier PA is reflected by the mirrors 92, 93 and enters the energy monitor module through the optical path tube 57. Thus, in this embodiment, the beam splitter 22 and the pulse energy sensor 23 in the energy monitor module 20 are optical elements that the laser beam emitted through the window 73 in the amplifier PA enters.

A pipe having an exhaust valve EV3 is connected to the optical path tube 55 in the amplifier PA. Opening of the exhaust valve EV3 is adjusted according to a control signal from the control unit CO. The connection of the pipe having the exhaust valve EV3 to the optical path tube 55 is an exhaust port EP3 that exhausts the gas in the optical path tube 55. Thus, the exhaust valve EV3 opens to exhaust the gas in the optical path tube 55 through the exhaust port EP3.

A pipe having an exhaust valve EV4 is connected to the optical path tube 56 in the amplifier PA. Opening of the exhaust valve EV4 is adjusted according to a control signal from the control unit CO. The connection of the pipe having the exhaust valve EV4 to the optical path tube 56 is an exhaust port EP4 that exhausts the gas in the optical path tube 56. Thus, the exhaust valve EV4 opens to exhaust the gas in the optical path tube 56 through the exhaust port EP4.

A pipe having an exhaust valve EV5 is further connected to the optical path tube 53 in the amplifier PA. Opening of the exhaust valve EV5 is adjusted according to a control signal from the control unit CO. The connection of the pipe having the exhaust valve EV5 to the optical path tube 53 is an exhaust port EP5 that exhausts the gas in the optical path tube 53. Thus, the exhaust valve EV5 opens to exhaust the gas in the optical path tube 53 through the exhaust port EP5. Thus, the gas in the casing 91, the optical path tube 57, the casing 21, and the optical path tube 53 is exhausted through the exhaust port EP5.

A pipe having an exhaust valve EV6 is connected substantially midway between the connection of the casing 81 of the optical transmission unit 80 to the optical path tube 51 and the connection thereof to the optical path tube 56. Opening of the exhaust valve EV6 is adjusted according to a control signal from the control unit CO. The connection of the pipe having the exhaust valve EV6 to the casing 81 is an exhaust port EP6 that exhausts the gas in the casing 81. Thus, the exhaust valve EV6 opens to exhaust the gas in the casing 81 through the exhaust port EP6.

The pipe having the exhaust valves EV3 to EV6 is connected to the different pipe to which the pipe having the exhaust valves EV1, EV2 in the master oscillator MO is connected. Thus, the gas exhausted through the exhaust ports EP3 to EP6 is exhausted through the different pipe into the casing 10.

In this embodiment, the pipe having a gas supply valve SV1 for the master oscillator MO is connected to the side of the output coupling mirror OC1 in the optical path tube 51 opposite to the chamber 30. Thus, the gas supply port SP1 for the master oscillator MO is provided on the side of the output coupling mirror OC1 in the optical path tube 51 opposite to the chamber 30. As described above, the space in the casing 81 communicates with the space in the optical path tube 51, and thus the gas supply port SP1 supplies the purge gas through the optical path tube 51 into the casing 81 of the optical transmission unit 80.

A plurality of pipes are connected to the purge gas manifold PM in addition to those connected to the purge gas manifold PM described in Embodiment 1, and a gas supply valve SV5 for the amplifier PA is provided in the middle of one of the pipes. Opening of the gas supply valve SV5 is adjusted according to a control signal from the control unit CO. The pipe having the gas supply valve SV5 is connected to the casing 91 of the optical transmission unit 90. The connection is a gas supply port SP5 for the amplifier PA that supplies the purge gas into the casing 91. Thus, the gas supply port SP5 supplies the purge gas through the casing 91 into the optical path tube 55, the optical path tube 57, the casing 21, and the optical path tube 53.

A different pipe branches off from a pipe connecting the purge gas manifold PM and the gas supply valve SV5, and a gas heating unit HT3 is connected to the branch pipe. The gas heating unit HT3 has, for example, a configuration similar to that of the gas heating unit HT1. Thus, a temperature of the purge gas heated by the gas heating unit HT3 is adjusted according to a control signal from the control unit CO.

A pipe having a gas supply valve SV7 is connected to the gas heating unit HT3. Opening of the gas supply valve SV7 is adjusted according to a control signal from the control unit CO. The pipe having the gas supply valve SV7 is connected to the optical path tube 55, and the connection of the pipe to the optical path tube 55 is a gas supply port SP7 that supplies the purge gas into the optical path tube 55. Thus, the gas supply port SP7 supplies the purge gas heated by the gas heating unit HT3. Thus, the gas supply port SP7 is a heated gas supply port that supplies the heated purge gas.

FIG. 15 shows a configuration of a section from one window 73 provided in the chamber 70 of the amplifier PA to the optical transmission unit 90. As shown in FIG. 15, the gas supply port SP7 is provided beside the window 73 to be directed to the window 73 in the optical path tube 55. The gas supply port SP7 may be formed to face any of surfaces of the window 73. Specifically, the gas supply port SP7 is provided in such a position that the purge gas is blown on an area of the window 73 closer to the chamber 70. Thus, an area of the window 73 closest to the gas supply port SP7 is the area closer to the chamber 70. A temperature of the purge gas supplied through the gas supply port SP7 is higher than a temperature in the chamber 70. If the temperature in the chamber 70 is, for example, about 65° C. like the temperature in the chamber 30, the temperature of the purge gas supplied through the gas supply port SP7 and blown on the window 73 is preferably, for example, 80° C. to 100° C. With such a temperature, a temperature on the side of the window 73 opposite to the chamber 70, that is, a temperature on the side on which the purge gas is blown is close to the temperature in the chamber 70. This can reduce a difference in temperature between opposite surfaces of the window 73.

An exhaust port EP3 in this embodiment is provided between the output coupling mirror OC2 as the optical element and the gas supply port SP7 when viewed perpendicularly to the traveling direction of the laser beam emitted through the window 73. This suppresses the purge gas supplied through the gas supply port SP7 from flowing toward the output coupling mirror OC2 as compared to the case where the exhaust port EP3 is provided on the side of the output coupling mirror OC2 opposite to the gas supply port SP7. The exhaust port EP3 is provided in such a position that the purge gas supplied through the gas supply port SP7 can easily flow along the surface of the window 73. Specifically, the exhaust port EP3 is provided in the optical path tube 55 on the opposite side to the gas supply port SP7 in a radial direction and near the area of the window 73 on the opposite side to the chamber 70, not the area on the chamber 70 side.

Since no gas heating unit is connected to a pipe connected to the gas supply port SP5, the gas supply port SP5 supplies an unheated purge gas. Thus, the gas supply port SP5 is an unheated gas supply port that supplies the unheated purge gas. The gas supply port SP5 in this embodiment is provided in the casing 91, and is thus provided on the side of the output coupling mirror OC2 as the optical element opposite to the exhaust port EP3.

Returning to FIG. 14, a gas supply valve SV6 for the amplifier PA is provided in the middle of another pipe connected to the purge gas manifold PM. Opening of the gas supply valve SV6 is adjusted according to a control signal from the control unit CO. The pipe having the gas supply valve SV6 is connected to the optical path tube 56. The connection is a gas supply port SP6 that supplies the purge gas into the optical path tube 56. Thus, the gas supply port SP6 supplies the purge gas through the optical path tube 56 into the casing 81 of the optical transmission unit 80.

A different pipe branches off from a pipe connecting the purge gas manifold PM and the gas supply valve SV6, and a gas heating unit HT4 is connected to the branch pipe. The gas heating unit HT4 has, for example, a configuration similar to that of the gas heating unit HT1. Thus, a temperature of the purge gas heated by the gas heating unit HT4 is adjusted according to a control signal from the control unit CO.

A pipe having a gas supply valve SV8 is connected to the gas heating unit HT4. Opening of the gas supply valve SV8 is adjusted according to a control signal from the control unit CO. The pipe having the gas supply valve SV8 is connected to the optical path tube 56, and the connection of the pipe to the optical path tube 56 is a gas supply port SP8 that supplies the purge gas into the optical path tube 56. Thus, the gas supply port SP8 supplies the purge gas heated by the gas heating unit HT4. Thus, the gas supply port SP8 is a heated gas supply port that supplies the heated purge gas.

FIG. 16 shows a configuration of a section from the other window 74 provided in the chamber 70 of the amplifier PA to the optical transmission unit 80 in FIG. 14. As shown in FIG. 16, the gas supply port SP8 is provided beside the window 74 to be directed to the window 74 in the optical path tube 56. The gas supply port SP8 may be formed to face any of surfaces of the window 74. Specifically, the gas supply port SP8 is provided in such a position that the purge gas is blown on an area of the window 74 closer to the chamber 70. Thus, an area of the window 74 closest to the gas supply port SP8 is the area closer to the chamber 70. A temperature of the purge gas supplied through the gas supply port SP8 is higher than the temperature in the chamber 70. The temperature of the purge gas supplied through the gas supply port SP8 and blown on the window 74 is similar to the temperature of the purge gas supplied through the gas supply port SP7. This can reduce a difference in temperature between opposite surfaces of the window 74.

The exhaust port EP4 in this embodiment is provided between the rear mirror RM as the optical element and the gas supply port SP8 when viewed perpendicularly to the traveling direction of the laser beam emitted through the window 74. This suppresses the purge gas supplied through the gas supply port SP8 from flowing toward the rear mirror RM as compared to the case where the exhaust port EP4 is provided on the side of the rear mirror RM opposite to the gas supply port SP8. The exhaust port EP4 is provided in such a position that the purge gas supplied through the gas supply port SP8 can easily flow along the surface of the window 74. Specifically, the exhaust port EP4 is provided in the optical path tube 56 on the opposite side to the gas supply port SP8 in a radial direction and near the area of the window 74 on the opposite side to the chamber 70, not the area on the chamber 70 side.

Since no gas heating unit is connected to the pipe connected to the gas supply port SP6, the gas supply port SP6 supplies an unheated purge gas. Thus, the gas supply port SP6 is an unheated gas supply port that supplies the unheated purge gas. The gas supply port SP6 in this embodiment is provided on the side of the rear mirror RM as the optical element opposite to the exhaust port EP4.

Returning to FIG. 14, in this embodiment, to the laser gas supply device 63, a pipe connected to the chamber 70 is connected in addition to the pipe connected to the chamber 30. Thus, the laser gas supply device 63 supplies the laser gas through this pipe into the chamber 70. The connection of this pipe to the chamber 70 is a laser gas supply port LSP2 that supplies the laser gas into the chamber 70.

To the exhaust device 64 in this embodiment, a pipe connected to the chamber 70 is connected in addition to the pipe connected to the chamber 30. Thus, the exhaust device 64 exhausts the gas in the chamber 30 and also the gas in the chamber 70 through the pipe into the casing 10. In this case, the exhaust device 64 adjusts an exhaust amount or the like according to a control signal from the control unit CO, and removes an F₂ gas from the gases exhausted from the chamber 30 and the chamber 70 using a halogen filter (not shown). The connection, to the chamber 70, of the pipe connected to the exhaust device 64 is a laser gas exhaust port LEP2 that exhausts the gas from the chamber 70.

8.2 Operation

In introduction or maintenance of the gas laser apparatus 100, for example, air flows into the optical path tube 51 and the optical path tube 52 in the master oscillator MO and into the optical path tube 55 and the optical path tube 56 in the amplifier PA. In this state, the control unit CO closes the exhaust valves EV1, EV2 and the gas supply valves SV0 to SV4 as in Embodiment 1. Further in this embodiment, the control unit CO closes the exhaust valves EV3 to EV6 and the gas supply valves SV5 to SV8. Thus, no purge gas is supplied into the optical path tubes 51, 52 in the master oscillator MO, no gas is exhausted through the optical path tubes 51, 52, no purge gas is supplied into the optical path tubes 55, 56 in the amplifier PA, and no gas is exhausted through the optical path tubes 55, 56.

Then, the control unit CO opens the exhaust valves EV1, EV2 for the master oscillator MO and the exhaust valves EV3, EV4 and the exhaust valves EV5, EV6 for the amplifier PA. At this time, the gas supply valves are closed, and thus no purge gas is supplied, and the gases in the optical path tubes 51, 52, 55, 56 are not exhausted.

Then, the control unit CO opens the gas supply valves SV0 to SV8. The unheated purge gas is supplied through the gas supply ports SP1, SP2, SP5, SP6 into the optical path tube 51, the casing 41, the casing 91, and the optical path tube 56, and the heated purge gas is supplied through the gas supply ports SP3, SP4, SP7, SP8 into the optical path tubes 51, 52, 55, 56. Thus, the windows 33, 34, 73, 74 are heated by the purge gas supplied through the gas supply ports SP3, SP4, SP7, SP8.

As described above, since the exhaust valves EV1, EV6 have been opened, the gas in the optical path tube 51 and the casing 81 is pushed out by the purge gas and exhausted through the exhaust ports EP1, EP6 through the pipe into the casing 10. Thus, the purge gas reduces an oxygen concentration in the optical path tube 51 and the casing 81, and the reduced oxygen concentration is maintained. Also, the gas flows on surfaces of the mirror 82, the output coupling mirror OC1, and the window 33, thereby suppressing adhesion of impurities or the like to the surfaces. At this time, the output coupling mirror OC1 is located between the gas supply port SP1 and the exhaust port EP1, and thus the unheated purge gas mainly flows around the output coupling mirror OC1 to suppress heating of the output coupling mirror OC1. Also, since the mirror 82 is located between the gas supply port SP1 and the exhaust port EP6, the unheated purge gas mainly flows around the mirror 82 to suppress heating of the mirror 82.

Since the exhaust valve EV2 has been also opened, the gas in the optical path tube 52 and the casing 41 is pushed out by the purge gas and exhausted through the exhaust port EP2 through the pipe into the casing 10 as in Embodiment 1. Thus, the purge gas reduces an oxygen concentration in the casing 41 and the second optical path tube 52, and the reduced oxygen concentration is maintained. The gas flows on surfaces of the grating 42, the prisms 43, 44, and the window 34, thereby suppressing adhesion of impurities or the like to the surfaces. At this time, the prism 43, 44 and at least part of the grating 42 as the optical elements are located between the gas supply port SP2 and the exhaust port EP2, and thus the unheated purge gas mainly flows around the optical elements to suppress heating of the optical elements.

Since the exhaust valves EV3, EV5 have been also opened, the gas in the optical path tube 55, the casing 91, the optical path tube 57, the casing 21, and the optical path tube 53 is pushed out by the purge gas and exhausted through the exhaust ports EP3, EP5 through the pipe into the casing 10. Thus, the purge gas reduces an oxygen concentration in the optical path tube 55, the casing 91, the optical path tube 57, the casing 21, and the optical path tube 53, and the reduced oxygen concentration is maintained. The gas flows on surfaces of the output coupling mirror OC2, the mirrors 92, 93, the beam splitter 22, and the window 73, thereby suppressing adhesion of impurities or the like to the surfaces. At this time, the output coupling mirror OC2 is located between the gas supply port SP5 and the exhaust port EP3, and thus the unheated purge gas mainly flows around the output coupling mirror OC2 to suppress heating of the output coupling mirror OC2. Also, since the mirrors 92, 93 and the beam splitter 22 are located between the gas supply port SP5 and the exhaust port EP5, the unheated purge gas mainly flows around the mirrors 92, 93 and the beam splitter 22. This suppresses heating of the mirrors 92, 93 and the beam splitter 22.

Since the exhaust valves EV4, EV6 have been also opened, the gas in the optical path tube 56 and the casing 81 is pushed out by the purge gas and exhausted through the exhaust ports EP4, EP6 through the pipe into the casing 10. Thus, the purge gas reduces an oxygen concentration in the optical path tube 56 and the casing 81, and the reduced oxygen concentration is maintained. The gas flows on surfaces of the mirror 83, the rear mirror RM, and the window 74, thereby suppressing adhesion of impurities or the like to the surfaces. At this time, the rear mirror RM is located between the gas supply port SP6 and the exhaust port EP4, and thus the unheated purge gas mainly flows around the rear mirror RM to suppress heating of the rear mirror RM. Also, since the mirror 83 is located between the gas supply port SP6 and the exhaust port EP6, the unheated purge gas mainly flows around the mirror 83 to suppress heating of the mirror 83.

The gas exhausted into the casing 10 is exhausted through the exhaust duct 11 to the outside of the casing 10.

Then, the control unit CO maintains this state for a predetermined period as in the comparative example. In this period, the oxygen concentrations in the optical path tubes 51 to 57 and the casings 21, 41, 81, 91 reach predetermined concentrations or lower.

Before completion of this period, the control unit CO causes the laser gas to be supplied into the chamber 30 and the chamber 70 and causes the supplied laser gas to be circulated. In this embodiment, a procedure of the laser gas being supplied into the chamber 30 and circulated is the same as that in the comparative example. A procedure of the laser gas being supplied into the chamber 70 and circulated is as described below. The control unit CO controls the exhaust device 64 to exhaust the gas in the chamber 70 through the laser gas exhaust port LEP2 into the casing 10. Then, the control unit CO controls the laser gas supply device 63 to supply a predetermined amount of laser gas through the laser gas supply port LSP2. As a result, the laser gas fills the chamber 70. The control unit CO also controls the motor 79 to rotate the cross flow fan 78. The cross flow fan 78 rotates to circulate the laser gas.

Then, the control unit CO causes the laser beam to be emitted from the output coupling mirror OC1 in the master oscillator MO as in Embodiment 1. The control unit CO controls the charger 75 and the switch in the pulse power module 76 to apply a high voltage between the electrodes 71, 72. When the high voltage is applied between the electrodes 71, 72, insulation between the electrodes 71, 72 is broken to cause discharge. By energy of the discharge, a laser medium contained in the laser gas between the electrodes 71, 72 is excited. The control unit CO controls the amplifier PA to excite the laser medium between the electrodes 71, 72 before the laser beam is emitted from the master oscillator MO. The laser beam emitted from the output coupling mirror OC1 is reflected by the mirrors 82, 83 in the optical transmission unit 80, and propagates through the rear mirror RM and the window 74 in the amplifier PA into the chamber 70. The laser beam causes stimulated emission of the excited laser medium between the electrodes 71, 72 and is amplified. Thus, the laser beam having a predetermined wavelength resonates between the output coupling mirror OC2 and the rear mirror RM and is further amplified. Then, part of the laser beam passes through the output coupling mirror OC2 and is emitted from the amplifier PA. The laser beam emitted from the amplifier PA is reflected by the mirrors 92, 93 in the optical transmission unit 90, and emitted through the optical path tube 57, the energy monitor module 20, and the optical path tube 53 and through the laser beam exit window OW.

In this embodiment, the energy monitor module 20 reflects part of the laser beam emitted from the amplifier PA with the beam splitter 22, and the pulse energy sensor 23 outputs, to the control unit CO, a signal according to intensity of energy of the laser beam. The control unit CO controls the chargers 35, 75 and the pulse power modules 36, 76 according to the signal to adjust power of the emitted laser beam.

8.3 Effect

With the gas laser apparatus 100 of this embodiment, the beam emitted from the master oscillator MO is amplified by the amplifier PA, thereby allowing the laser beam with higher power to be emitted. As in Embodiment 1, even if the windows 33, 34 in the master oscillator MO are heated when the laser beam is emitted, a smaller thermal shock can be applied on the windows 33, 34. The surfaces of the windows 73, 74 in the amplifier PA are heated by the purge gas supplied through the gas supply ports SP7, SP8. Thus, when the laser beam is emitted, a difference between the temperatures of the windows 73, 74 on the side of the chamber 70 and the temperatures thereof on the side of the optical path tubes 55, 56 becomes smaller than that in the case where the windows 73, 74 are not heated by the purge gas. Thus, even if the windows 73, 74 are heated when the laser beam is emitted from the amplifier PA, a smaller thermal shock can be applied on the windows 73, 74. Thus, the gas laser apparatus 100 of this embodiment can have high durability.

In this embodiment, as long as the purge gas is supplied into each of the closed space including the space in the optical path tube 51, the closed space including the space in the optical path tube 52, the closed space including the space in the optical path tube 55, and the closed space including the space in the optical path tube 56, and the heated purge gas is supplied into any of the closed spaces, the heated purge gas needs not be supplied to the other closed spaces. In this case, it is preferable that no heated purge gas is supplied into the optical path tubes 51, 52 in the master oscillator MO, and the heated purge gas is supplied into the optical path tubes 55, 56 in the amplifier PA. Alternatively, the heated purge gas may be supplied into the optical path tube 55 on a laser beam exit side of the amplifier PA, and no heated purge gas may be supplied into the optical path tubes 51, 52 in the master oscillator MO and the optical path tube 56 on a laser beam entrance side of the amplifier PA. As such, the heated purge gas may be selectively supplied to the window through which the laser beam with relatively high power passes, thereby reducing cost required to heat the purge gas.

In this embodiment, the gas supply valves SV1 to SV8 are opened at the same timing, but for example, the timing when the gas supply valves SV1, SV2, SVS, SV6 are opened may be different from the timing when the gas supply valves SV3, SV4, SV7, SV8 are opened. In at least part of the period when the laser beam is emitted, the gas supply valves SV3, SV4, SV7, SV8 are opened, and the heated purge gas is supplied through the gas supply ports SP3, SP4, SP7, SP8.

In this embodiment, the master oscillator MO may be constituted by a different laser device such as a fiber laser device. The amplifier PA does not need to include the rear mirror and the output coupling mirror OC2. In this case, the beam does not resonate in the amplifier PA, but the laser beam passes through the chamber 70 and is amplified.

In this embodiment, for the areas to which the heated purge gas is supplied, the configurations in Embodiments 2 to 5 may be applied.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser apparatus comprising:
a chamber filled with a laser gas;
a window provided in the chamber and through which a laser beam passes;
an optical path tube connected to the chamber to surround a position of the window in the chamber;
a heated gas supply port configured to supply a heated purge gas into a closed space including a space in the optical path tube; and
an exhaust port configured to exhaust a gas in the closed space.

2. The gas laser apparatus according to claim 1, wherein the heated gas supply port is provided in such a position that the purge gas is blown on the window.

3. The gas laser apparatus according to claim 2, wherein the window is tilted with respect to a traveling direction of the laser beam, and
the heated gas supply port is provided in such a position that the purge gas is blown on an area of the window closer to the chamber.

4. The gas laser apparatus according to claim 2, further comprising an optical element that the laser beam emitted through the window enters,
wherein the exhaust port is provided between the heated gas supply port and the optical element when viewed perpendicularly to a traveling direction of the laser beam emitted through the window.

5. The gas laser apparatus according to claim 4, further comprising an unheated gas supply port that is provided on a side of the optical element opposite to the exhaust port and is configured to supply an unheated purge gas into the closed space.

6. The gas laser apparatus according to claim 1, further comprising a window cover that covers the window in the optical path tube and has a slit through which the laser beam passes,
wherein the heated gas supply port is provided in such a position that the purge gas is supplied between the window and the window cover.

7. The gas laser apparatus according to claim 6, wherein the window cover has a multilayer structure including a plurality of cover members arranged at intervals.

8. The gas laser apparatus according to claim 6, wherein the window cover is made of a thermal insulation material.

9. The gas laser apparatus according to claim 1, further comprising:
an optical element that the laser beam emitted through the window enters; and
a wall that is provided in a position between the window and the optical element in the optical path tube and has a slit through which the laser beam passes,
wherein the heated gas supply port is provided closer to the window than the wall.

10. The gas laser apparatus according to claim 9, wherein the exhaust port is provided between the wall and the optical element.

11. The gas laser apparatus according to claim 1, wherein at least part of an outer peripheral surface of the optical path tube is covered with a thermal insulation layer.

12. The gas laser apparatus according to claim 1, wherein at least part of the optical path tube is made of a thermal insulation material.

13. The gas laser apparatus according to claim 1, wherein a temperature of the purge gas is higher than a temperature in the chamber.

14. The gas laser apparatus according to claim 1, further comprising a gas heating unit configured to heat the purge gas to be supplied to the heated gas supply port,
wherein the gas heating unit includes an electric heater or a ceramic heater.

15. The gas laser apparatus according to claim 1, wherein the chamber heats part of a pipe through which the purge gas to be supplied to the heated gas supply port flows.

16. The gas laser apparatus according to claim 15, wherein the chamber is made of metal, and
part of the pipe extends on an outer surface of the chamber.

17. The gas laser apparatus according to claim 1, wherein the chamber is at least one of a master oscillator chamber configured to emit oscillating light and an amplifier chamber configured to amplify incident light and to emit amplified light.

18. An electronic device manufacturing method comprising:
causing a laser beam emitted from a gas laser apparatus to enter an exposure apparatus; and
exposing a photosensitive substrate to the laser beam within the exposure apparatus to manufacture an electronic device,
the gas laser apparatus including a chamber filled with a laser gas, a window provided in the chamber and through which the laser beam passes, an optical path tube connected to the chamber to surround a position of the window in the chamber, a heated gas supply port configured to supply a heated purge gas into a closed space including a space in the optical path tube, and an exhaust port configured to exhaust a gas in the closed space.
